(19) United States
(12) Patent Application Publication
(10) Pub. No.: US 2025/0159894 A1
(43) Pub. Date: May 15, 2025

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Zhou He, Wuhan (CN); Meng Xiao, Wuhan (CN); Kuan Dong, Wuhan (CN); Longdong Liu, Wuhan (CN); Gang Zhang, Wuhan (CN)

(21) Appl. No.: 18/516,053

(22) Filed: Nov. 21, 2023

(30) Foreign Application Priority Data
Nov. 14, 2023 (CN) 202311530703.0

(51) Int. Cl. H10B 43/50; H10B 43/10; H10B 43/27

(52) U.S. Cl. CPC H10B 43/50; H10B 43/10; H10B 43/27

(57) ABSTRACT

Three-dimensional (3D) memory devices and fabricating methods thereof are disclosed. One disclosed semiconductor device comprises a stack structure comprising an array region and a contact region, and a gate line slit structure extending vertically through the stack structure and laterally along a first lateral direction to divide the stack structure into memory blocks. The gate line slit structure comprises a first dummy channel structure located at a boundary between the array region and the contact region, a first gate line slit segment extending laterally from the first dummy channel structure into the array region, and a second gate line slit segment extending laterally from the first dummy channel structure into the contact region.

### CROSS-REFERENCE TO RELATED APPLICATIONS

This application claims the benefit of priority to Chinese Application No. 202311530703.0, filed on Nov. 14, 2023, which is incorporated herein by reference in its entirety. This application is also related to U.S. application Ser. No. ______, Attorney Docketing No.: 10018-01-0507-US, filed on even date, entitled “THREE-DIMENSIONAL MEMORY DEVICES AND FABRICATING METHODS THEREOF,” and U.S. application Ser. No. ______, Attorney Docketing No.: 10018-01-0507-US3, filed on even date, entitled “THREE-DIMENSIONAL MEMORY DEVICES AND FABRICATING METHODS THEREOF,” both of which are hereby incorporated by reference in their entireties.

### TECHNICAL FIELD

The present disclosure generally relates to the field of semiconductor technology, and more particularly, to three-dimensional (3D) memory devices, and fabricating methods for forming three-dimensional (3D) memory devices.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As such, memory density for planar memory cells approaches an upper limit. A three-dimensional (3D) memory architecture can address the density limitation in planar memory cells.

As semiconductor technology advances, 3D memory devices, such as 3D NAND memory devices, keep scaling more film layers to improve the area utilization of wafers. In some existing 3D NAND memory devices, as the number of film layers increases and the structure of the film layer becomes more complicated, the silicon substrate used as a carrier of the film layers may not support the wafer deformation caused by film stresses, which may eventually lead to an arcing of the wafer. Further, as the number of oxide/nitride (ON) layers increases, an etch depth of gate line slit (GLS) increases accordingly, resulting changes of the critical dimensions of the GLS, thereby increasing a risk of unstable structure due to stress and other factors. Such unstable structure may cause the memory finger crooking/collapse, wafer bow effects, and affect subsequent 3D memory device fabricating processes, such as increasing overlay error in the lithographic alignment process.

### BRIEF SUMMARY

Implementations of three-dimensional (3D) memory devices and fabricating methods thereof are disclosed herein.

One aspect of the present disclosure provides a semiconductor device, comprising: a stack structure comprising an array region and a contact region; and a gate line slit structure extending vertically through the stack structure and laterally along a first lateral direction to divide the stack structure into memory blocks, the gate line slit structure comprising: a first dummy channel structure located at a boundary between the array region and the contact region, a first gate line slit segment extending laterally from the first dummy channel structure into the array region, and a second gate line slit segment extending laterally from the first dummy channel structure into the contact region.

In some implementations, the semiconductor device further comprises channel structures each vertically extending through the stack structure and located in the array region; and second dummy channel structures each vertically extending through the stack structure and located in the contact region.

In some implementations, the stack structure in the array region comprises conductive layers and first dielectric layers alternatively stacked in a vertical direction; and the stack structure in the contact region comprises: a first contact portion adjacent to the second gate line slit segment and comprising the conductive layers and the first dielectric layers alternatively stacked in the vertical direction, and a second contact portion separated from the second gate line slit segment by the first contact portion, and comprising first dielectric layers and second dielectric layers alternatively stacked in the vertical direction.

In some implementations, the second dummy channel structures are each vertically extending through the first contact portion.

In some implementations, a first width of the first dummy channel structure along the first lateral direction is greater than a second width of the first dummy channel structure along a second lateral direction perpendicular to the first lateral direction.

In some implementations, the first dummy channel structure comprises a high-k layer, a first oxide layer, a nitride layer, a second oxide layer, a semiconductor layer, and a filling structure.

In some implementations, the first dummy channel structure comprises an oxide structure and semiconductor segments laterally surrounded by the oxide structure.

In some implementations, the oxide structure comprises: a convex sidewall surface adjacent to the first gate line slit segment; and a concave sidewall surface adjacent to the second gate line slit segment.

In some implementations, each of the first gate line slit segment and the second gate line slit segment comprises a wall structure laterally extending in the first lateral direction and insulated from the conductive layers.

In some implementations, the semiconductor device further comprises gate line contact structures each extending vertically in the second contact portion and laterally in contact with a corresponding conductive layer in the first contact portion.

In some implementations, each gate line contact structure comprises: a conductive landing layer in the second contact portion and laterally in contact with the corresponding conductive layer; and a conductive via vertically through the second dielectric layers and first dielectric layers above the conductive landing layer and in contact with the conductive landing layer.

Another aspect of the present disclosure provides a method for forming a semiconductor device, comprising: forming a dielectric stack comprising alternative second dielectric layers and first dielectric layers; forming a row of first through holes laterally aligned along a first lateral direction, and each vertically through the dielectric stack, forming sacrificial filling structures in the first through holes; removing the sacrificial filling structure from one first through hole at a boundary between an array region and a contact region; forming a first dummy channel structure in the one first through hole; removing the sacrificial filling structures from the other first through holes and portions of the dielectric stack to form a first trench in the array region and a second trench in the contact region; and forming a first gate line slit segment in the first trench and a second gate line slit segment in the second trench.

In some implementations, the method further comprises: when forming the row of first through holes, forming second through holes in an array region; and forming third through holes in a contact region and adjacent to the first through holes; wherein a first distance between adjacent first through holes is less than a second distance between adjacent second through holes.

In some implementations, the method further comprises when forming sacrificial filling structures in the first through holes, forming sacrificial filling structures in the second through holes and the third through holes.

In some implementations, the method further comprises when removing the sacrificial filling structure from the one first through hole, removing the sacrificial filling structures from the second through holes and the third through holes.

In some implementations, when forming the first dummy channel structure, forming channel structures in the second through holes; and forming second dummy channel structures in the third through holes.

In some implementations, the method further comprises: forming a first sacrificial wall in the first trench and a second sacrificial wall in the second trench; removing the first sacrificial wall to reopen the first trench; replacing the second dielectric layers in the array region to conductive layers through the reopened first trench; removing the second sacrificial wall to reopen the second trench; and replacing portions of the second dielectric layers in the contact region that are adjacent to the second trench to conductive layers.

In some implementations, forming the first dummy channel structure comprises: forming a first oxide layer on a sidewall of the one first through hole; forming a nitride layer on the first oxide layer; forming a second oxide layer on the nitride layer; forming a semiconductor layer on the second oxide layer; and forming a filing structure on the semiconductor layer to fill the one first through hole.

In some implementations, the method further comprises: when removing the sacrificial filling structures from the other first through holes and portions of the dielectric stack, further removing portions of the first oxide layer, the nitride layer, and the second oxide layer, to expose sidewalls of the semiconductor layer in the first and second trenches; oxidizing exposed sidewalls of the semiconductor layer; when replacing the second dielectric layers in the array region, further removing remaining portions of the nitride layer to form curved openings; and oxidizing portions of the second sacrificial wall exposed by the curved openings.

In some implementations, the method further comprises forming a high-k layer on the sidewall of the one first through hole; wherein the first oxide layer is formed on the high-k layer.

In some implementations, forming the first and second gate line slit segments comprises: forming an insulating layer on sidewalls and bottoms of the first and second trenches; and forming wall structures on the insulating layer to fill the first and second trenches.

In some implementations, the method further comprises forming a gate line contact structure through a remaining portions of the dielectric stack in the contact region, and in contact with a corresponding conductive layer in the contact region.

In some implementations, forming the gate line contact structure comprises: forming a contact hole though portions of the dielectric stack to expose one sacrifice layer in a same level of the corresponding conductive layer; removing portions of the one sacrifice layer to form a lateral recess to expose the corresponding conductive layer; forming a landing conductive layer in the lateral recess and in contact with the corresponding conductive layer; and forming a conductive via in the contact hole to contact with the landing conductive layer.

Another aspect of the present disclosure provides a memory device, comprising: a stack structure comprising: a first conductive/dielectric stack in an array region, a second conductive/dielectric stack in a contact region, and a dielectric stack in the contact region; and a gate line slit structure extending vertically through the stack structure and laterally along a first lateral direction to divide the stack structure into memory blocks, the gate line slit structure comprising: a first dummy channel structure located at a boundary between the array region and the contact region, a first gate line slit segment extending laterally from the first dummy channel structure into the array region, and a second gate line slit segment extending laterally from the first dummy channel structure into the contact region; and channel structures each extending vertically through the first conductive/dielectric stack; second dummy channel structures each extending vertically through the second conductive/dielectric stack and adjacent to the second gate line slit segment; and gate line contact structures each extending vertically in the dielectric stack and laterally in contact with corresponding conductive layers of the second conductive/dielectric stack.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a block diagram of a system having a memory device, according to some aspects of the present disclosure.

FIG. 2A illustrates a diagram of a memory card having a memory device, in accordance with some implementations.

FIG. 2B illustrates a diagram of a solid-state drive (SSD) having a memory in accordance with some implementations.

FIG. 3 illustrates a top-down view of a 3D memory device, according to some implementations of the present disclosure.

FIG. 4 illustrates a perspective view of a portion of a 3D memory array structure, according to some implementations of the present disclosure.

FIG. 5 illustrates a top-down perspective view of a portion of a 3D memory array structure, according to some implementations of the present disclosure.

FIG. 6 illustrates a flow diagram of a method for forming a 3D memory device in accordance with some implementations of the present disclosure.

FIG. 7A illustrates a schematic diagram of a portion of a 3D memory device at a certain fabricating stage of the method shown in FIG. 6 in a top-down perspective view, according to some implementations of the present disclosure.

FIG. 7B illustrates a schematic diagram of a portion of a 3D memory device at a certain fabricating stage of the method shown in FIG. 6 in a cross-sectional side view, according to some implementations of the present disclosure.

FIG. 8A illustrates a schematic diagram of a portion of a 3D memory device at a certain fabricating stage of the method shown in FIG. 6 in a top-down perspective view, according to some implementations of the present disclosure.

FIG. 8B illustrates a schematic diagram of a portion of a 3D memory device at a certain fabricating stage of the method shown in FIG. 6 in a cross-sectional side view, according to some implementations of the present disclosure.

FIG. 9A illustrates a schematic diagram of a portion of a 3D memory device at a certain fabricating stage of the method shown in FIG. 6 in a top-down perspective view, according to some implementations of the present disclosure.

FIG. 9B illustrates a schematic diagram of a portion of a 3D memory device at a certain fabricating stage of the method shown in FIG. 6 in a cross-sectional side view, according to some implementations of the present disclosure.

FIG. 9C illustrates a schematic diagram of a portion of a 3D memory device at a certain fabricating stage of the method shown in FIG. 6 in another cross-sectional side view, according to some implementations of the present disclosure.

FIG. 10A illustrates a schematic diagram of a portion of a 3D memory device at a certain fabricating stage of the method shown in FIG. 6 in a top-down perspective view, according to some implementations of the present disclosure.

FIG. 10B illustrates a schematic diagram of a portion of a 3D memory device at a certain fabricating stage of the method shown in FIG. 6 in a cross-sectional side view, according to some implementations of the present disclosure.

FIG. 10C illustrates a schematic diagram of a portion of a 3D memory device at a certain fabricating stage of the method shown in FIG. 6 in another cross-sectional side view, according to some implementations of the present disclosure.

FIG. 10D illustrates a schematic diagram of a portion of a 3D memory device at a certain fabricating stage of the method shown in FIG. 6 in an enlarged top-down perspective view, according to some implementations of the present disclosure.

FIG. 10E illustrates a schematic diagram of a portion of a 3D memory device at a certain fabricating stage of the method shown in FIG. 6 in an enlarged top-down perspective view, according to some other implementations of the present disclosure.

FIG. 11A illustrates a schematic diagram of a portion of a 3D memory device at a certain fabricating stage of the method shown in FIG. 6 in a top-down perspective view, according to some implementations of the present disclosure.

FIG. 11B illustrates a schematic diagram of a portion of a 3D memory device at a certain fabricating stage of the method shown in FIG. 6 in a cross-sectional side view, according to some implementations of the present disclosure.

FIG. 11C illustrates a schematic diagram of a portion of a 3D memory device at a certain fabricating stage of the method shown in FIG. 6 in another cross-sectional side view, according to some implementations of the present disclosure.

FIG. 11D illustrates a schematic diagram of a portion of a 3D memory device at a certain fabricating stage of the method shown in FIG. 6 in an enlarged top-down perspective view, according to some implementations of the present disclosure.

FIG. 11E illustrates a schematic diagram of a portion of a 3D memory device at a certain fabricating stage of the method shown in FIG. 6 in an enlarged top-down perspective view, according to some other implementations of the present disclosure.

FIG. 12A illustrates a schematic diagram of a portion of a 3D memory device at a certain fabricating stage of the method shown in FIG. 6 in a top-down perspective view, according to some implementations of the present disclosure.

FIG. 12B illustrates a schematic diagram of a portion of a 3D memory device at a certain fabricating stage of the method shown in FIG. 6 in a cross-sectional side view, according to some implementations of the present disclosure.

FIG. 12C illustrates a schematic diagram of a portion of a 3D memory device at a certain fabricating stage of the method shown in FIG. 6 in a cross-sectional side view, according to some implementations of the present disclosure.

FIG. 12D illustrates a schematic diagram of a portion of a 3D memory device at a certain fabricating stage of the method shown in FIG. 6 in an enlarged top-down perspective view, according to some implementations of the present disclosure.

FIG. 12E illustrates a schematic diagram of a portion of a 3D memory device at a certain fabricating stage of the method shown in FIG. 6 in an enlarged top-down perspective view, according to some other implementations of the present disclosure.

FIG. 13A illustrates a schematic diagram of a portion of a 3D memory device at a certain fabricating stage of the method shown in FIG. 6 in a top-down perspective view, according to some implementations of the present disclosure.

FIG. 13B illustrates a schematic diagram of a portion of a 3D memory device at a certain fabricating stage of the method shown in FIG. 6 in a cross-sectional side view, according to some implementations of the present disclosure.

FIG. 13C illustrates a schematic diagram of a portion of a 3D memory device at a certain fabricating stage of the method shown in FIG. 6 in another cross-sectional side view, according to some implementations of the present disclosure.

FIG. 13D illustrates a schematic diagram of a portion of a 3D memory device at a certain fabricating stage of the method shown in FIG. 6 in an enlarged top-down perspective view, according to some implementations of the present disclosure.

FIG. 13E illustrates a schematic diagram of a portion of a 3D memory device at a certain fabricating stage of the method shown in FIG. 6 in an enlarged top-down perspective view, according to some other implementations of the present disclosure.

FIG. 14A illustrates a schematic diagram of a portion of a 3D memory device at a certain fabricating stage of the method shown in FIG. 6 in a top-down perspective view, according to some implementations of the present disclosure.

FIG. 14B illustrates a schematic diagram of a portion of a 3D memory device at a certain fabricating stage of the method shown in FIG. 6 in a cross-sectional side view, according to some implementations of the present disclosure.

FIG. 14C illustrates a schematic diagram of a portion of a 3D memory device at a certain fabricating stage of the method shown in FIG. 6 in another cross-sectional side view, according to some implementations of the present disclosure.

FIG. 14D illustrates a schematic diagram of a portion of a 3D memory device at a certain fabricating stage of the method shown in FIG. 6 in an enlarged top-down perspective view, according to some implementations of the present disclosure.

FIG. 14E illustrates a schematic diagram of a portion of a 3D memory device at a certain fabricating stage of the method shown in FIG. 6 in an enlarged top-down perspective view, according to some other implementations of the present disclosure.

FIG. 15A illustrates a schematic diagram of a portion of a 3D memory device at a certain fabricating stage of the method shown in FIG. 6 in a top-down perspective view, according to some implementations of the present disclosure.

FIG. 15B illustrates a schematic diagram of a portion of a 3D memory device at a certain fabricating stage of the method shown in FIG. 6 in a cross-sectional side view, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to effect such feature, structure or characteristic in connection with other implementations whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of an Homogeneous or inhomogeneous continuous structure that has a thickness less than the thickness of the continuous structure. For example, a layer can be located between any pair of lateral planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnection layer can include one or more conductor and contact layers (in which contacts, interconnect lines, and/or vias are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D memory device” refers to a semiconductor device with vertically-oriented strings of memory cell transistors (i.e., region herein as “memory strings,” such as NAND strings) on a laterally-oriented substrate so that the memory strings extend in the vertical direction with respect to the substrate. As used herein, the term “vertical/vertically” means nominally perpendicular to a lateral surface of a substrate.

As described above, 3D NAND memory devices keep scaling more film layers to improve the area utilization of wafers. In some existing 3D NAND memory devices, as the number of film layers increases and the structure of the film layer becomes more complicated, the silicon substrate used as a carrier of the film layers may not support the wafer deformation caused by film stresses, which may eventually lead to an arcing of the wafer. Further, as the number of oxide/nitride (ON) layers increases, an etch depth of gate line slit (GLS) increases accordingly, resulting changes of the critical dimensions of the GLS, thereby increasing a risk of unstable structure due to stress and other factors. Such unstable structure may cause the memory finger crooking/collapse, wafer bow effects, and affect subsequent 3D memory device fabricating processes, such as increasing overlay error in the lithographic alignment process.

Accordingly, various implementations in accordance with the present disclosure provide 3D memory devices and fabricating methods for forming 3D memory devices with a novel design for gate line slit (GLS) structures for a memory array (also referred to herein as an “array device”). Based on the GLS expansion process, the patterning process of the channel holes, GLS openings, and contact holes can be merged into a single mask. The memory finger supports can be designed between GLS structures segments by cancelling the traditional long GLS isolation structure. Dummy contact structures can be used as memory finger supports and can be formed in the same processes of forming the contact structures. And the isolation function can be realized through a silicon nitride recess process and oxide deposition process, and together with the short GLS structures segments.

Since there is no long GLS that runs through the entire plane, the risk of unstable structure due to stress can be suppressed by using short GLS structures segments and memory finger supports. The filled oxide and polysilicon material in the short GLS structures segments and memory finger supports can significantly decrease device defects including memory finger crooking/collapse and/or wafer bow effects. Further, by merging the channel structure formation processes and the GLS structure formation processes, the application of photolithography process can be reduced, thereby reducing the process difficulty and the production costs. In summary, the present disclosure can solve the fabricating issues caused by structural stresses, thereby breaking the technical bottleneck in the research and development of higher-level 3D memory devices.

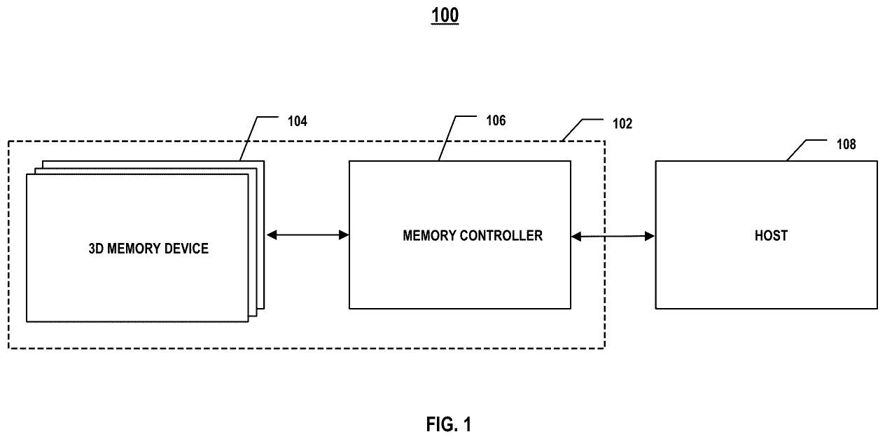

FIG. 1 illustrates a block diagram of a system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory devices disclosed herein, such as a NAND Flash memory device. Consistent with the scope of the present disclosure, memory controller 106 may control the multi-pass programming on memory device 104 such that an NGS operation is enabled on all memory cells, even those passed the respective verify operations, in a non-last programming pass of the multi-pass programming. The peripheral circuits, such as the word line drivers, may apply a low voltage, e.g., ground (GND) voltage, on the DSGs of each memory string coupled to the selected word line, and may apply a low or negative voltage on the selected word line to enable an NGS operation on all memory cells coupled to the selected word line during a non-last programming pass.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, programming memory device 104. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

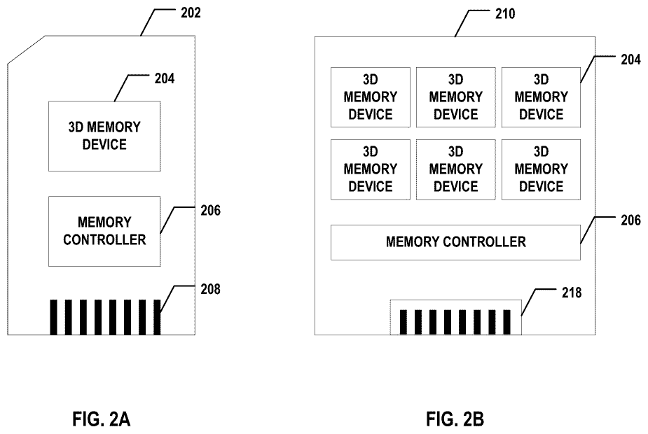

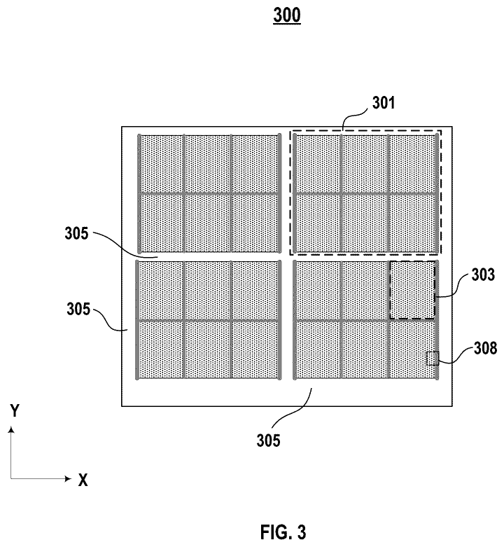

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 208 coupling memory card 202 with a host (e.g., host 108 in FIG. 1). In another example as shown in FIG. 2B, memory controller 106 and multiple memory devices 104 may be integrated into an SSD 210. SSD 210 can further include an SSD connector 218 coupling SSD 210 with a host (e.g., host 108 in FIG. 1). In some implementations, the storage capacity and/or the operation speed of SSD 210 is greater than those of memory card 202.

FIG. 3 illustrates a top-down view of a 3D memory device 300, according to some implementations of the present disclosure. 3D memory device 300 can be a memory chip (package), a memory chip or any portion of a memory chip, and can include one or more memory planes 301, each of which can include a plurality of memory blocks 303. Identical and concurrent operations can take place at each memory plane 301. Memory block 303, which can be megabytes (MB) in size, can be the smallest size to carry out erase operations. Shown in FIG. 3, 3D memory device 300 includes four memory planes 301 and each memory plane 301 includes six memory blocks 303. Each memory block 303 can include a plurality of memory cells, where each memory cell can be addressed through interconnections such as bit lines and word lines. The bit lines and word lines can be laid out perpendicularly (e.g., in rows and columns, respectively), forming an array of metal lines. In FIG. 3, the direction of word lines is referred as a first lateral direction and labeled as X-direction, and the direction of bit lines is referred as a second lateral direction and labeled as Y-direction. In this disclosure, memory block 303 is also referred to as a “memory array” or “array.” The memory array is the core area in a memory device, performing storage functions.

3D memory device 300 can include a periphery region 305, an area surrounding memory planes 301. Periphery region 305 can contain many digital, analog, and/or mixed-signal circuits to support functions of the memory array, for example, page buffers, row and column decoders and sense amplifiers. Peripheral circuits use active and/or passive semiconductor devices, such as transistors, diodes, capacitors, resistors, etc., as would be apparent to a person of ordinary skill in the art. It is noted that, the arrangement of memory planes 301 in 3D memory device 300 and the arrangement of memory blocks 303 in each memory plane 301 illustrated in FIG. 3 are only provided as an example, which does not limit the scope of the present disclosure.

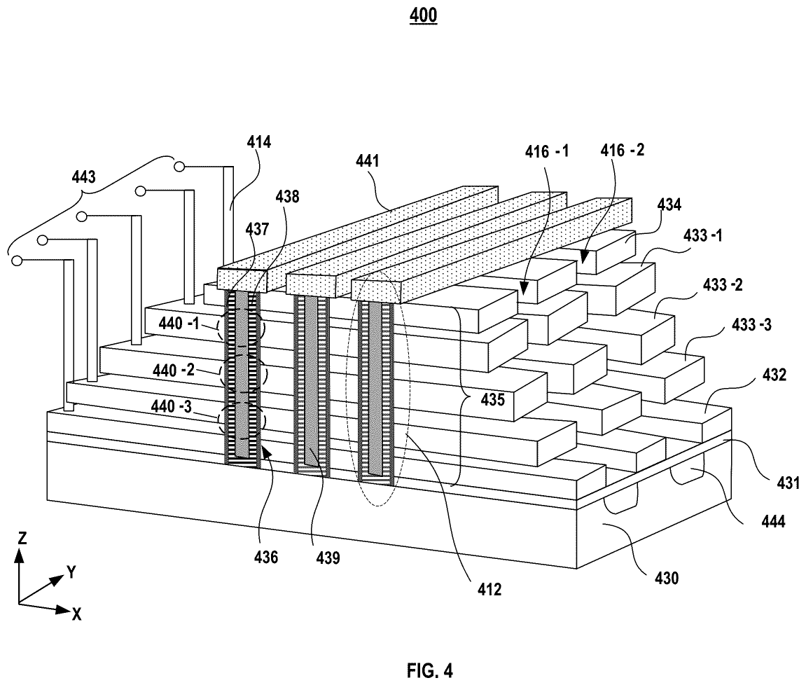

FIG. 4 illustrates a perspective view of a portion of a 3D memory array structure 400, according to some implementations of the present disclosure. Memory array structure 400 includes a substrate 430, an insulating film 431 over the substrate 430, one or more tiers of bottom select gates (BSGs) 432 over the insulating film 431, and a plurality of tiers of control gates 433, also referred to as “word lines (WLs),” stacking on top of the BSGs 432 to form a stack structure 435 of alternating conductive and dielectric layers. The dielectric layers adjacent to the tiers of control gates are not shown in FIG. 4 for clarity.

The control gates 433 of each tier are separated by slit structures 416-1 and 416-2 through stack structure 435. Memory array structure 400 can include one or more tiers of top select gates (TSGs) 434 over the stack of control gates 433. The stack of TSG 434, control gates 433 and BSG 432 are also referred to as “gate structures.” Memory array structure 400 further includes memory strings 412 and doped source line regions 344 in portions of substrate 430 between adjacent BSGs 432. Each memory strings 412 includes a channel hole 436 extending through insulating film 431 and stack structure 435 of alternating conductive and dielectric layers. Memory strings 412 can also include a memory film 437 (also referred as “functional layer”) on a sidewall of the channel hole 436, a channel layer 438 over the memory film 437, and a core filling film 2339 surrounded by the channel layer 438. A memory cell 440 can be formed at the intersection of control gate 433 and memory string 412. Memory array structure 400 further includes a plurality of bit lines (BLs) 441 connected with memory strings 412 over TSGs 434. Memory array structure 400 can include a plurality of metal interconnect lines 443 connected with the gate structures through a plurality of contact structures 414.

In FIG. 4, for illustrative purposes, three tiers of control gates 433-1, 433-2, and 433-3 are shown together with one tier of TSG 434 and one tier of BSG 432. In this example, each memory string 412 can include three memory cells 440-1, 440-2 and 440-3, corresponding to the control gates 433-1, 433-2 and 433-3, respectively. In some implementations, the number of control gates and the number of memory cells can be more than three to increase storage capacity. Memory array structure 400 can also include other structures, for example, TSG cuts, common source contacts, and dummy channel structures. These structures are not shown in FIG. 4 for simplicity.

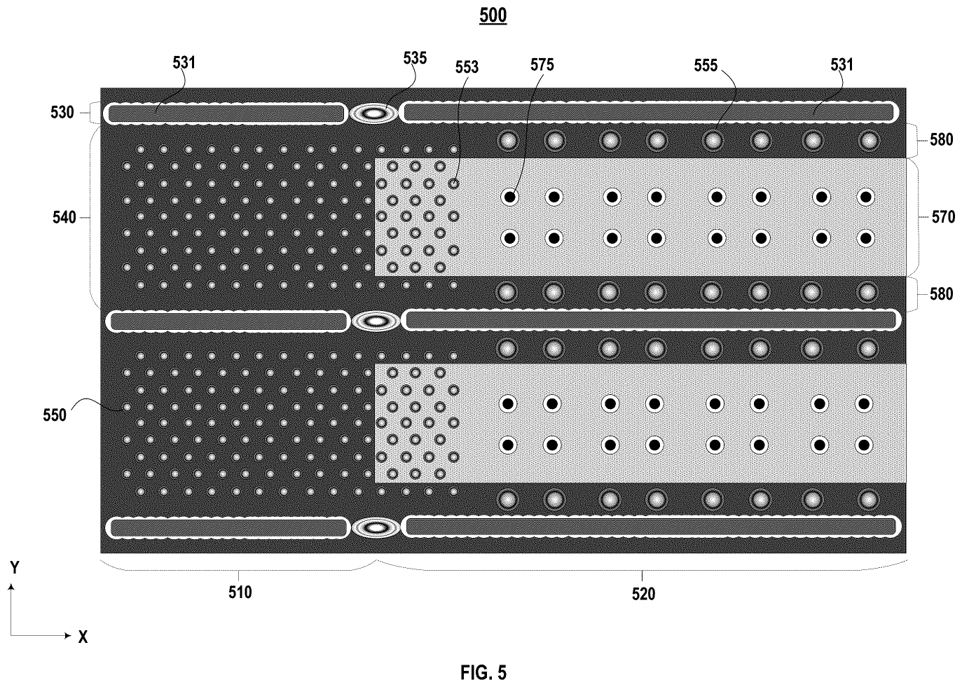

Referring to FIG. 5, a schematic diagram of a portion 500 of 3D memory device, such as region 308 of FIG. 3 is shown in an enlarged top-down view, according to some implementations of the present disclosure. As shown, portion 500 of 3D memory device can include an array region 510 including a plurality of channel structures 550, and a contact region 520 including a plurality of contact structures 575. Multiple slits can laterally extend in parallel along a word line direction (i.e., X-direction) and vertically extend through the stack structure. A gate line slit (GLS) structure 530 can be formed in each slit to divide the memory array into multiple memory fingers 540. Each memory finger 540 can include multiple (e.g., nine) rows of channel structures 550 arranged in a staggered manner between two adjacent GLS structures 530. The channel structures 550 can vertically extend through a conductive/dielectric stack structure.

As discussed above, as the number of film layers increases and the structure of the film layer becomes more complicated, the silicon substrate used as a carrier of the film layers may not support the wafer deformation caused by film stresses, which may eventually lead to an arcing of the wafer. Further, as 3D memory devices keep scaling more number of ON layers to improve the area utilization of wafers, the etch depth of GLS increases accordingly, resulting a risk of collapse of the memory fingers 540 between adjacent GLS structures 530 in the subsequent process due to stress and other factors. Collapse of memory fingers 540 can affect subsequent 3D memory device fabricating processes, such as increasing overlay error in the lithographic alignment process.

The present disclosure provides various segment GLS structure designs as a technical solution to avoid the above issues. In some implementations as shown in FIG. 5, each GLS structure 530 can include two gate line slit (GLS) structure segments 531 aligned along the word line direction (X-direction), and one first dummy channel structure 535 located between the two GLS structure segments 531 in the word line direction. In some implementations, each GLS structure segment 531 comprises a wall structure laterally extending in the word line direction (X-direction) and insulated from the conductive layers of the stack structure. In some implementations, one GLS structure segment 531 is located in the array region 510, the other GLS structure segment 531 is located in the contact region 520, and the first dummy channel structure 535 can be located at a boundary between the array region 510 and the contact region 520. In some implementations, a cross section of the first dummy channel structure 535 along the lateral plane (i.e., X-Y plane) can have an oval shape with the longitudinal axis along the word line direction (X-direction). In some other implementations not shown in FIG. 5, the cross section of the first dummy channel structure 535 along the lateral plane can have any other suitable shape, such as a round shape. In some implementations, the width of the GLS structure segment 531 in the bit line direction (Y-direction) can be substantially equal to the width of the first dummy channel structure 535 in the bit line direction.

As shown in FIG. 5, each memory finger 540 in the contact region 520 can include two conductive/dielectric stack regions 580 adjacent to the GLS structure segments 531, and one dielectric stack region 570 between the two conductive/dielectric stack regions 580. In some implementations, each conductive/dielectric stack regions 580 includes a conductive/dielectric stack comprising conductive layers and dielectric layers alternatively stacked in the vertical direction (Z-direction), the dielectric stack region 570 includes a dielectric stack comprising two different dielectric layers alternatively stacked in the vertical direction.

As shown in FIG. 5, a plurality of second dummy channel structures 555 can be located in the conductive/dielectric stack regions 580 of the contact region 520, and a plurality of third dummy channel structures 553 can be located in the dielectric stack region 570 of the contact region 520 adjacent to the array region 510. In some implementations, the channel structures 550, the first dummy channel structures 535, the second dummy channel structures 555, and the third dummy channel structures 553 can include similar structures. For example, each of the channel structures 550, the first dummy channel structures 535, the second dummy channel structures 555, and the third dummy channel structures 553 can include a functional layer, a channel layer, and a filling structure, which will be described in detail below.

As shown in FIG. 5, a plurality of gate line contact structures 575 can extend vertically in the dielectric stack region 570 of the contact region 520. In some implementations, each gate line contact structure 575 comprises a conductive via structure vertically extends through an upper portion of the dielectric stack structure, and a conductive landing layer in contact with the lower end of the conductive via. The conductive landing layer can laterally connect to a corresponding conductive layer of the conductive/dielectric stack in the conductive/dielectric stack region 580.

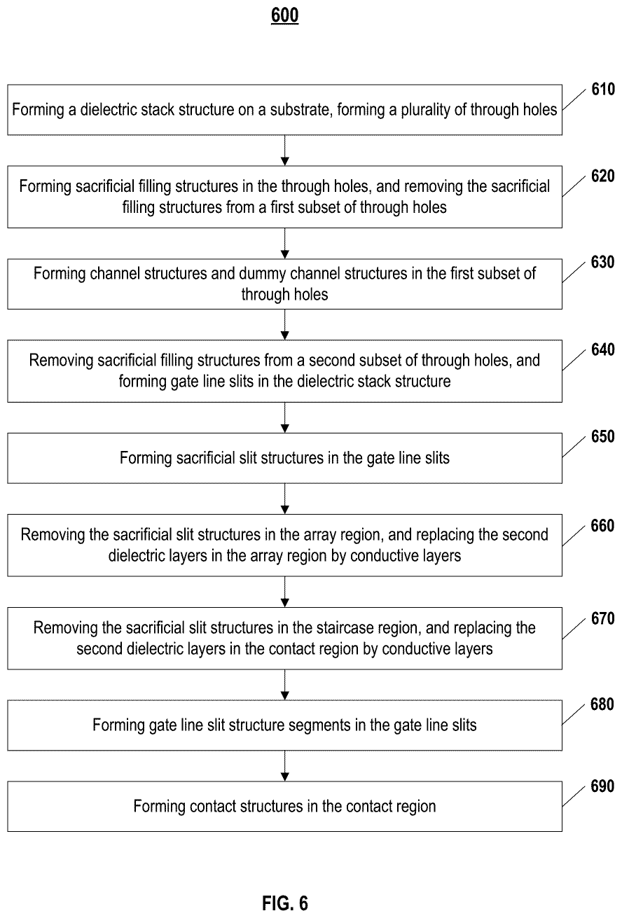

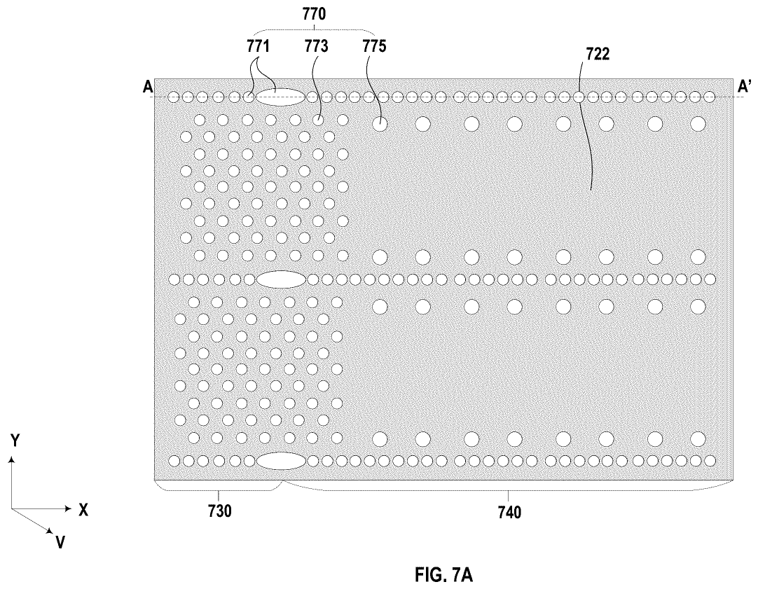

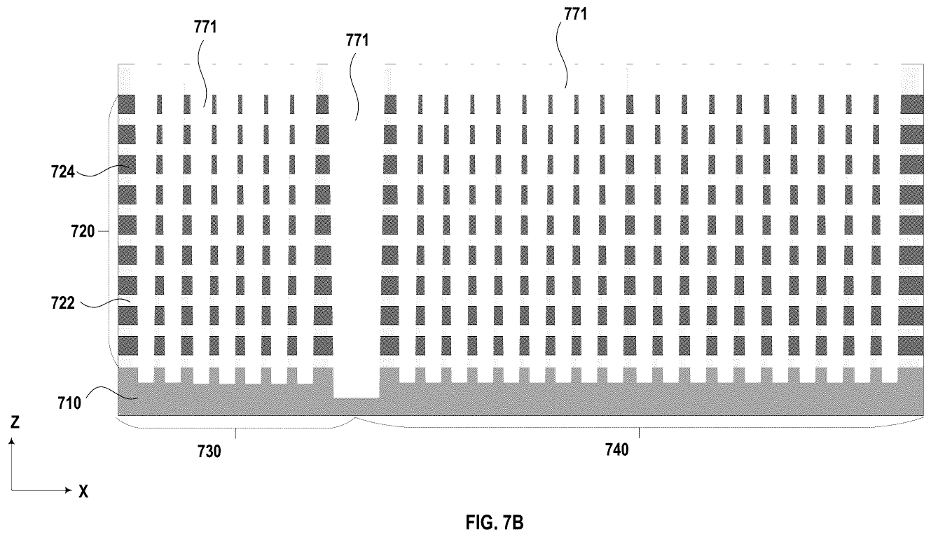

Referring to FIG. 6, a flow diagram of a method 600 for forming a 3D memory device is shown in accordance with some implementations of the present disclosure. FIGS. 7A-7B, 8A-8B, 9A-9C, 10A-10E, 11A-11E, 12A-12E, 13A-13E, 14A-14E and 15A-15B illustrate schematics of portions of a 3D memory device at certain fabricating stages of the method 600 shown in FIG. 6 in various views, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, the method can start at operation 610, in which a dielectric stack structure can be formed on a substrate, and a plurality of through holes can be formed in an array region and a contact region of the dielectric stack structure. FIG. 7A illustrates a schematic diagram of the 3D structure after forming the plurality of through holes at operation 610 in a top-down perspective view, according to some implementations of the present disclosure. FIG. 7B illustrates a schematic diagram of a portion of the 3D structure in a cross-sectional side view along the AA′ line shown in FIG. 7A, according to some implementations of the present disclosure.

As shown in FIG. 7B, in some implementations, the substrate 710 can be any suitable semiconductor substrate having any suitable structure, such as a monocrystalline single-layer substrate, a polycrystalline silicon (polysilicon) single-layer substrate, a polysilicon and metal multi-layer substrate, etc.

The dielectric stack structure 720 including a plurality of dielectric layer pairs can be formed on the substrate 710. The dielectric stack structure 720 can include an alternating stack of a first dielectric layer 722 (e.g., silicon oxide) and a second dielectric layer 724 (e.g., silicon nitride) that is different from the first dielectric layer 722, for example. The plurality of first dielectric layers 722 and second dielectric layers 724 are extended in a lateral direction that is parallel to the surface of the substrate 710. In some implementations, there are more layers than the dielectric layer pairs made of different materials and with different thicknesses in the dielectric stack structure 720. The dielectric stack structure 720 can be formed by one or more thin film deposition processes including, but not limited to, Chemical Vapor Deposition (CVD), Physical Vapor Deposition (PVD), Atomic Layer Deposition (ALD), or any combination thereof.

In some implementations, the dielectric stack structure 720 can include a plurality of silicon oxide/nitride layer pairs. Each dielectric layer pair includes a layer of silicon oxide 722 and a layer of silicon nitride 724. The plurality of oxide/nitride layer pairs are also referred to herein as an “alternating oxide/nitride stack.” That is, in the dielectric stack structure 720, multiple oxide layers 722 (shown in the areas with solid gray) and multiple nitride layers 724 (shown in the areas with meshes) alternate in a vertical direction. In other words, except a top and a bottom layer of a given alternating oxide/nitride stack, each of the other oxide layers 722 can be sandwiched by two adjacent nitride layers 724, and each of the nitride layers 724 can be sandwiched by two adjacent oxide layers 722.

Oxide layers can each have the same thickness or have different thicknesses. For example, the thickness of each oxide layer can be in a range from 10 nm to 100 nm, preferably about 25 nm. Similarly, nitride layers can each have the same thickness or have different thicknesses. For example, the thickness of each nitride layer can be in a range from 10 nm to 100 nm, preferably about 35 nm.

It is noted that, in the present disclosure, the oxide layers 722 and/or nitride layers 724 can include any suitable oxide materials and/or nitride materials. For example, the oxide materials can include silicides, and the element of nitride materials can include, but not limited to, tungsten (W), cobalt (Co), copper (Cu), aluminum (Al), doped silicon, silicides, or any combination thereof. In some implementations, the oxide layers can be silicon oxide layers, and the nitride layers can be silicon nitride layer.

The dielectric stack structure 720 can include any suitable number of layers of the oxide layers 722 and the nitride layers 724. In some implementations, the total number of layers of the oxide layers 722 and the nitride layers 724 in the dielectric stack structure 720 is equal to or larger than 64. That is, a number of oxide/nitride layer pairs can be equal to or larger than 32. In some implementations, the alternating oxide/nitride stack 200 includes more oxide layers or more nitride layers with different materials and/or thicknesses than the oxide/nitride layer pair.

As shown in FIGS. 7A-7B, a plurality of through holes 770 can be formed in the array region 730 and the contact region 740 of the dielectric stack structure 720 at operation 610. In some implementations, the plurality of through holes 770 can include first through holes 771 laterally aligned along the word line direction (X-direction) and each extending vertically through the dielectric stack 720. In some implementations, the first through holes 771 can be located in both of the array region 730 and the contact region 740. In some implementations, the plurality of through holes 770 can further include second through holes 773 located in the array region 730. In some implementations, the second through holes 773 can be arranged in a staged array form in the array region 730 and between adjacent rows of first through holes 771. In some implementations, the plurality of through holes 770 can further include third through holes 775 located in the contact region 740. In some implementations, the third through holes 775 can be located adjacent to the first through holes 771. In some implementations, the first through holes 771, the second through holes 773, and the third through holes 775 can be formed simultaneously. In some implementations, a first distance between adjacent first through holes 771 can be less than a second distance between adjacent second through holes 773 and a third distance between adjacent third through holes 775.

A process of forming the plurality of through holes 770 can include forming a hard mask layer (not shown) on the dielectric stack structure 720, and coating a photoresist layer (not shown) on the hard mask layer. A pattering process can be performed to pattern the hard mask layer. Using the hard mask layer as a mask, an etching process can be followed to etch the dielectric stack structure 720 to form the plurality of through holes 770. Each of plurality of through holes 770 can completely penetrate the dielectric stack structure 720 and extend into the substrate 710. The etching process to form the plurality of through holes 770 can be a dry etching, a wet etching, or a combination thereof. After the etching process, the photoresist layer and the hard mask layer can be removed. In some implementations, the plurality of through holes 770 and the channel holes formed in operation 610 can be formed in a same patterning process by using a single mask.

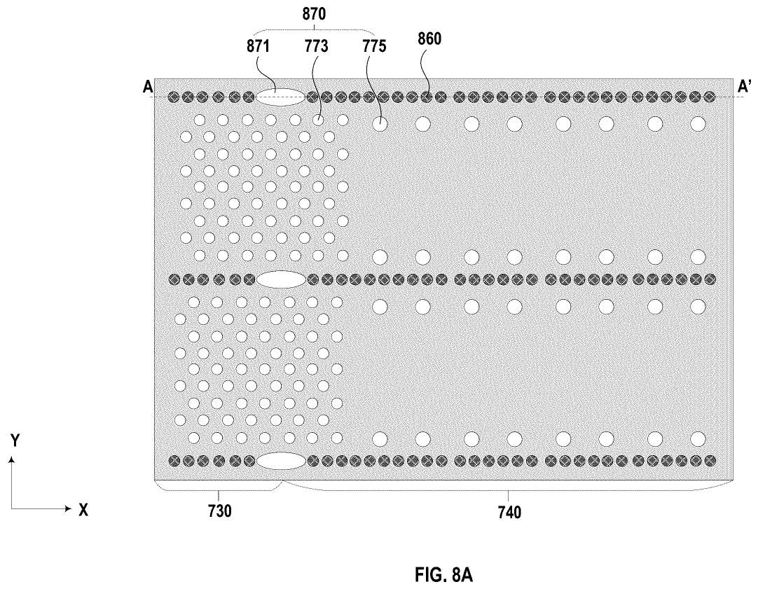

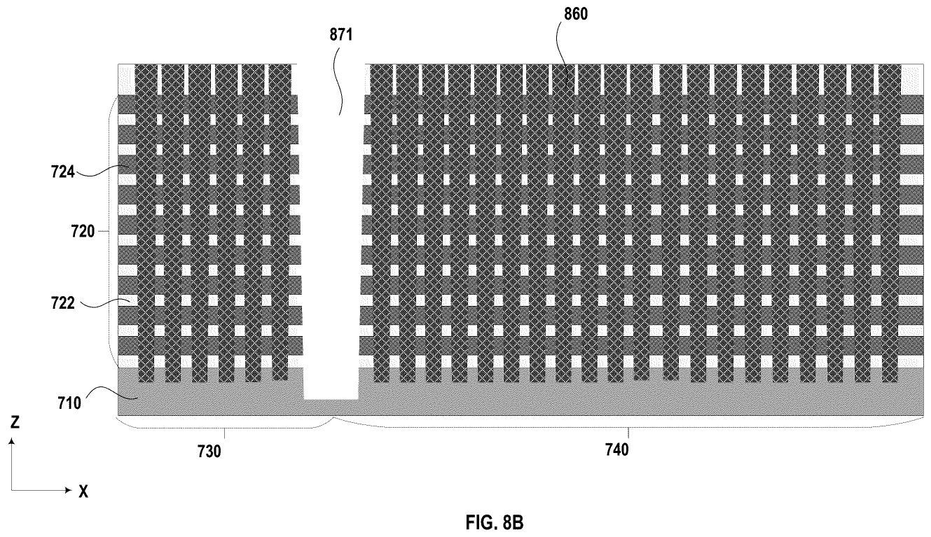

Referring back to FIG. 6, the method 600 can proceed to operation 620, in which a plurality of sacrificial filling structures can be formed in the plurality of through holes, and the sacrificial filling structures can be removed from a first subset of through holes. The first subset of through holes can be used to as channel holes and/or dummy channel holes for forming channel structures and dummy channel structures in the subsequent process. FIG. 8A illustrates a schematic diagram of the 3D structure after forming the plurality of through holes at operation 620 in a top-down perspective view, according to some implementations of the present disclosure. FIG. 8B illustrates a schematic diagram of a portion of the 3D structure in a cross-sectional side view along the AA′ line shown in FIG. 8A, according to some implementations of the present disclosure.

As shown in FIGS. 8A-8B, a plurality of sacrificial filling structures 860 can be formed in the through holes 770. In some implementations, a deposition process can be performed to fill the through holes 770, including the first through holes 771, the second through holes 773, and the third through holes 775, with any suitable sacrificial material (e.g., carbon-based materials) to form the sacrificial filling structures 860. It is noted that, the sacrificial material of the sacrificial filling structures 860 can have a sufficiently high etching selectivity in respect of the materials of the first dielectric layers 722 and the second dielectric layers 724, such that a subsequent etching process of the sacrificial filling structures 860 can have minimal impact on the first dielectric layers 722 and the second dielectric layers 724.

As shown in FIGS. 8A-8B, the sacrificial filling structures 860 can be removed from a first subsets of the through holes 870. Specifically, the sacrificial filling structures 860 can be removed from a column of first through holes 871 at the boundary between the array region 730 and the contact region 740, and from the second through holes 773 and the third through holes 775 by using any suitable etching process, e.g., an isotropic dry etch or a wet etch. The etching process can have sufficiently high etching selectivity of the sacrificial material of the sacrificial filling structures 860 over the materials of the first dielectric layers 722 and second dielectric layers 724, such that the etching process can have minimal impact on the first dielectric layers 722 and second dielectric layers 724. As such, the column the first through holes 871, the second through holes 773, and the third through holes 775 can be formed again for forming channel structures or dummy channel structures.

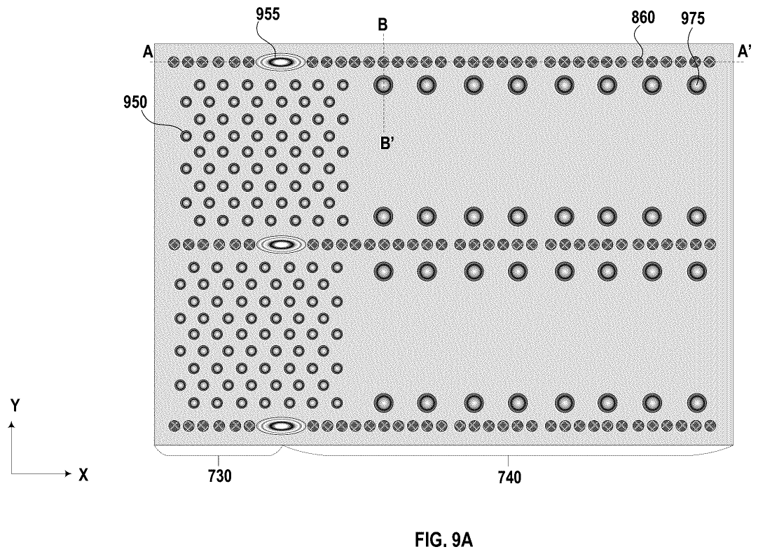

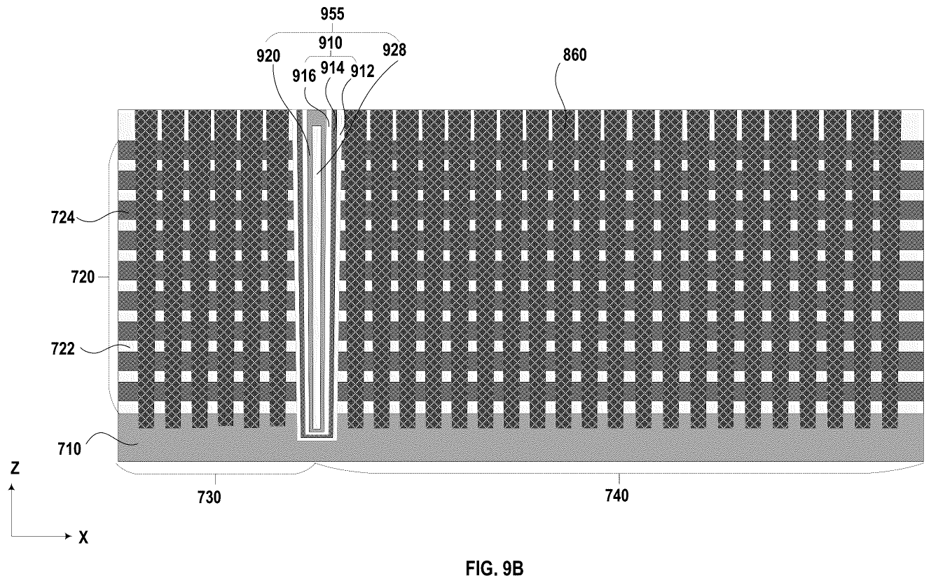

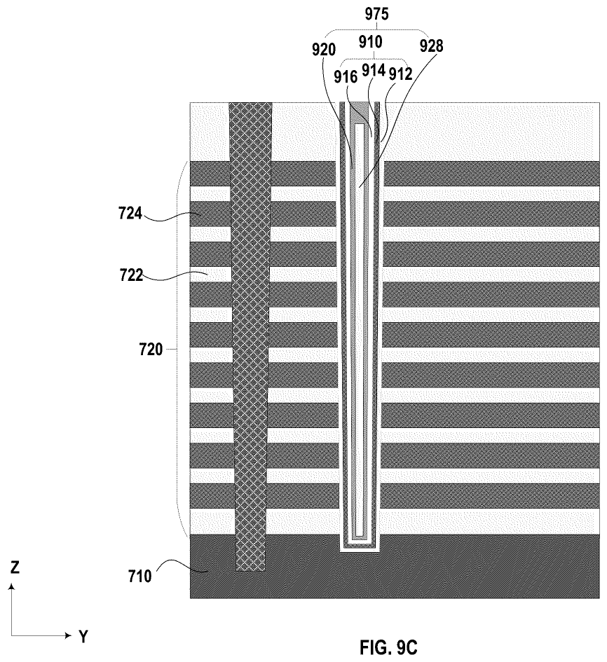

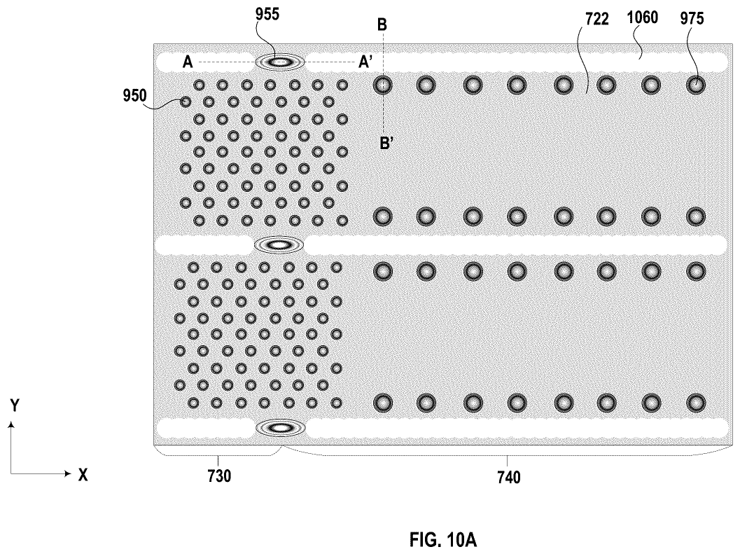

Referring back to FIG. 6, method 600 can proceed to operation 630, in which a plurality of channel structures and dummy channel structures can be formed in the dielectric stack structure. FIG. 9A illustrates a schematic diagram of the 3D structure after operation 620 in a top-down perspective view, according to some implementations of the present disclosure. FIG. 9B illustrates a schematic diagram of a portion of the 3D structure in a cross-sectional side view along the AA′ line shown in FIG. 9A, according to some implementations of the present disclosure. FIG. 9C illustrates a schematic diagram of a portion of the 3D structure in a cross-sectional side view along the BB′ line shown in FIG. 9A, according to some implementations of the present disclosure.

As shown in FIGS. 9A, 9B and 9C, in some implementations, a plurality of channel structures 950 can be formed in the second through holes 773 in the array region 730, a plurality of first dummy channel structure 955 can be formed in the column of the first through holes 871, and a plurality of second dummy channel structure 975 can be formed in the column of the third through holes 775. Each channel structure 950, first dummy channel structure 955, and/or second dummy channel structure 975 can vertically extend through the dielectric stack structure 720 into the substrate 710. In some implementations, the channel structures 950, the first dummy channel structures 955, and the second dummy channel structure 975 can include similar structures including, an optional high-K dielectric layer (not shown), a functional layer 910 on the sidewall of the channel hole or covering the high-K dielectric layer, a channel layer 920 covering the functional layer 910, and a filling structure 928 enclosed by the channel layer 920. In some implementations, the functional layer 910 can include a barrier layer 912, a storage layer 914, and a tunneling layer 916. In some implementations, the plurality of first dummy channel structures 955 can have an oval-shaped cross section in the lateral plane (X-Y plane) with a longitudinal axis in the word line direction (X-direction).

In some implementations, the plurality of channel structures 950 can form a staggered array form. In some implementations, the array of channel structures 950 can include a plurality of rows of channel structures 950. Each row of channel structures 950 can be aligned along the word line direction (X-direction). Adjacent rows of channel structures 950 can be misaligned. In some implementations, the array of channel structures 950 can include a plurality of columns of channel structures 950. Each column of channel structures 950 can be aligned along the bit line direction (Y-direction). Adjacent columns of channel structures 950 can be misaligned. In some implementations, the first dummy channel structures 955 can be located at the boundary between the array region 730 and the contact region 740. In some implementations, the second dummy channel structures 975 can be located in the contact region 740 and adjacent to the remaining sacrificial filling structures 860.

In some implementations, fabricating process for forming the channel structures 950, first dummy channel structures 955, and second dummy channel structures 975 can include forming an epitaxial layer (not shown) at a bottom of each channel hole/dummy channel hole. In some implementations, the epitaxial layer can be a polycrystalline silicon (polysilicon) layer formed by using a selective epitaxial growth (SEG) process. For example, an SEG pre-clean process can be performed to clean the multiple channel holes. A following deposition process can be performed to form a polysilicon layer at the bottom of each channel hole. In some implementations, any suitable doping process, such as an ion metal plasma (IMP) process, can be performed on the polysilicon layer to form the epitaxial layer. In some implementations, the epitaxial layer may not be directly formed on the surface of substrate 710. One or more layers can be formed between the epitaxial layer and the substrate 710. That is, the epitaxial layer overlays the substrate 710.

In some implementations, fabrication processes to form the channel structures 950, first dummy channel structures 955, and second dummy channel structures 975 can include forming an optional high-K dielectric layer (not shown) on the sidewall of each channel hole, and forming a functional layer 910 to cover the high-K dielectric layer. The functional layer 910 can be a composite dielectric layer, such as a combination of a barrier layer 912, a storage layer 914, and a tunneling layer 916. The high-K dielectric layer, the functional layer 910, including the barrier layer 912, the storage layer 914, and the tunneling layer 916, can be formed by one or more thin film deposition processes, such as ALD, CVD, PVD, any other suitable processes, or any combination thereof.

In some implementations, the barrier layer 912 and/or the high-K dielectric layer can be formed between the storage layer 914 and the sidewall of the channel hole/dummy channel hole. The barrier layer 912 and/or the high-K dielectric layer can be used for blocking the outflow of the electronic charges. In some implementations, the barrier layer 912 can be a silicon oxide layer or a combination of silicon oxide/silicon nitride/silicon oxide (ONO) layers. In some implementations, the high-K dielectric layer includes any suitable high dielectric constant (high k-value) dielectrics (e.g., aluminum oxide).

The storage layer 914 can be formed between the tunneling layer 916 and the barrier layer 912. Electrons or holes from the channel layer can tunnel to the storage layer 914 through the tunneling layer 916. The storage layer 914 can be used for storing electronic charges (electrons or holes) for memory operation. The storage or removal of charge in the storage layer 914 can impact the on/off state and/or a conductance of the semiconductor channel. The storage layer 914 can include one or more films of materials including, but are not limited to, silicon nitride, silicon oxynitride, a combination of silicon oxide and silicon nitride, or any combination thereof. In some implementations, the storage layer 914 can include a nitride layer formed by using one or more deposition processes.

The tunneling layer 916 can be formed on the sidewall of the storage layer 914. The tunneling layer can be used for tunneling electronic charges (electrons or holes). The tunneling layer 916 can include dielectric materials including, but not limited to, silicon oxide, silicon nitride, silicon oxynitride, or any combination thereof. In some implementations, the tunneling layer 916 can be an oxide layer formed by using a deposition process.

In some implementations, the fabrication processes of forming the channel structures 950, first dummy channel structures 955, and second dummy channel structures 975 further include forming a channel layer 920 covering the sidewall of the functional layer 910. In some implementations, channel layer 920 can be an amorphous silicon layer or a polysilicon layer formed by using a thin film deposition process, such as ALD, CVD, PVD, or any other suitable process.

In some implementations, fabrication processes to form the channel structures 950, first dummy channel structures 955, and second dummy channel structures 975 further include forming a filling structure 928 to cover the channel layer 920 and fill the channel hole. In some implementations, the filling structure 928 can be an oxide layer formed by using any suitable deposition process, such as ALD, CVD, PVD, etc. In some implementations, the filling structure 928 can include one or more airgaps (not shown).

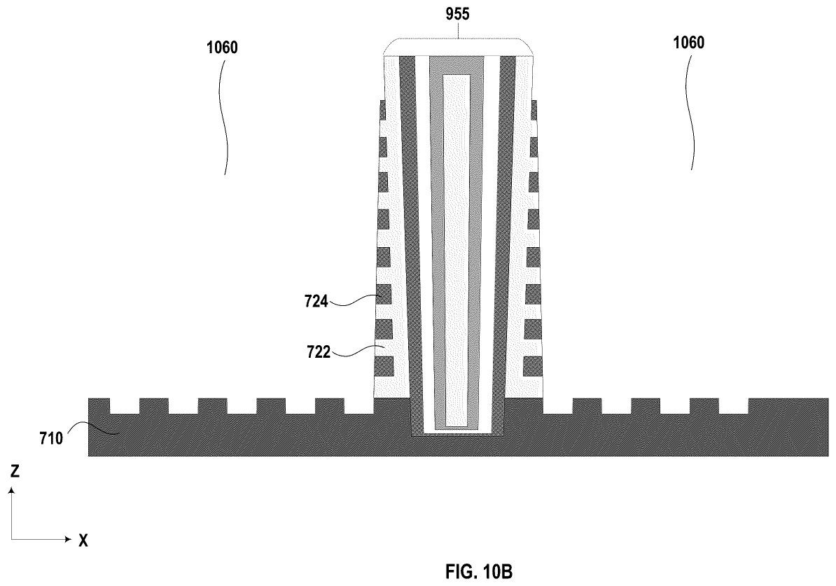

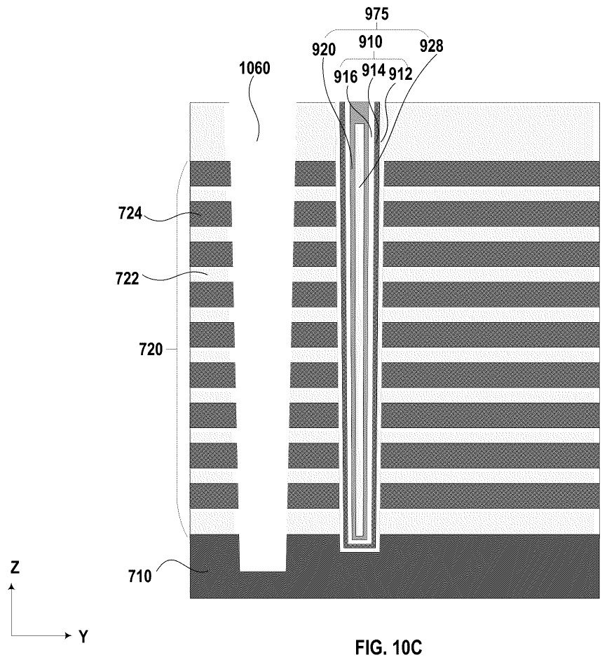

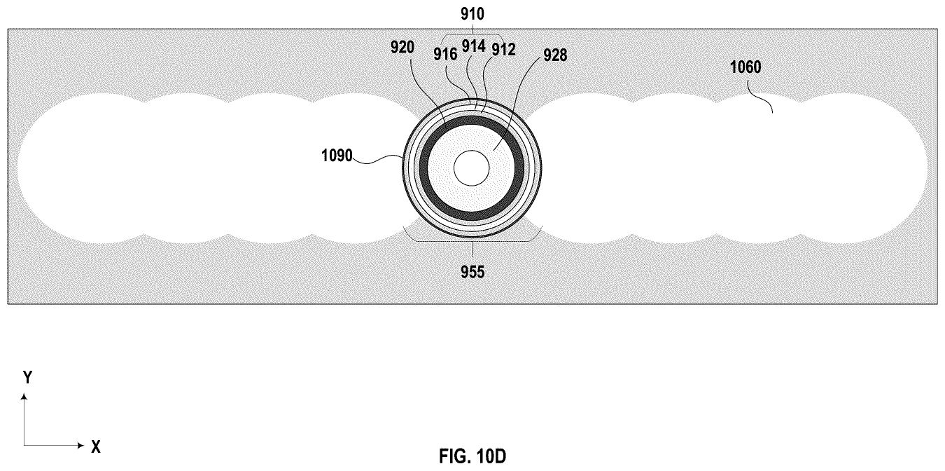

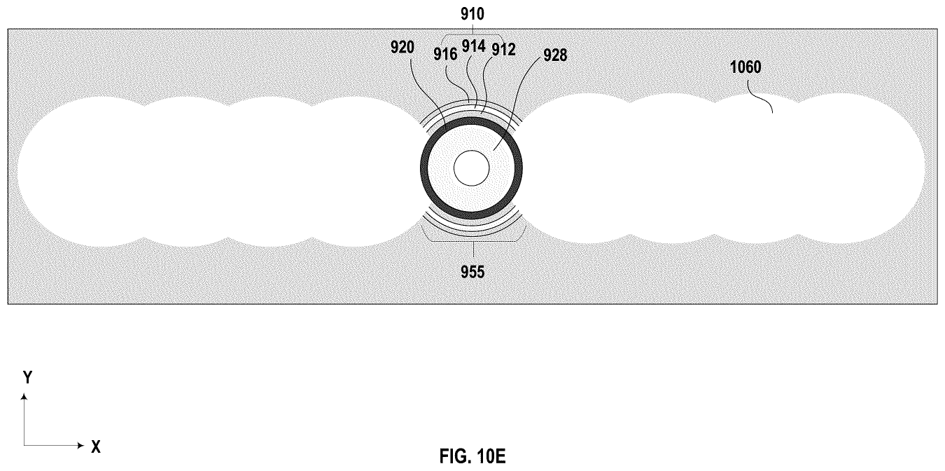

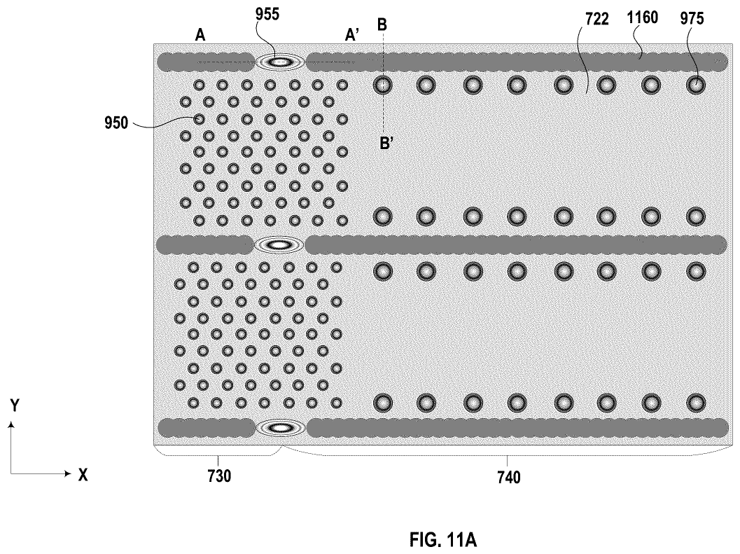

Referring back to FIG. 6, the method proceeds to operation 640, in which the sacrificial filling structures can be removed from a second subset of through holes, and multiple gate line slits (GLSs) can be formed in the dielectric stack structure. FIG. 10A illustrates a schematic diagram of the 3D structure after operation 640 in a top-down perspective view, according to some implementations of the present disclosure. FIG. 10B illustrates a schematic diagram of a portion of the 3D structure in a cross-sectional side view along the AA′ line shown in FIG. 10A, according to some implementations of the present disclosure. FIG. 10C illustrates a schematic diagram of a portion of the 3D structure in a cross-sectional side view along the BB′ line shown in FIG. 10A, according to some implementations of the present disclosure. FIG. 10D illustrates a schematic diagram of a portion of the 3D structure after operation 640 in an enlarged top-down view, according to some implementations of the present disclosure. FIG. 10E illustrates a schematic diagram of a portion of the 3D structure after operation 640 in an enlarged top-down view, according to some other implementations of the present disclosure.

As shown in FIGS. 10A-10E, the sacrificial filling structures 860 in the remaining first through holes 771 other than the column of first through holes 871, and portions of the dielectric stack structure 720 adjacent to the sacrificial filling structures 860 can be removed to form a plurality of gate line slits (GLSs) 1060. The multiple GLSs 1060 can each extend vertically penetrate through the dielectric stack structure 720 into the substrate 710. As shown in FIGS. 10A-10B, and 10D-10E, the first dummy channel structure 955 can be located between the GLSs 1060, the first dummy channel structure 955 and the GLSs 1060 are laterally aligned in a straight line along the word line direction (X-direction). In some implementations, when the first dummy channel structure 955 includes a high-K dielectric layer 1090 as shown in FIG. 10D, the GLSs 1060 can expose the sidewall of the high-K dielectric layer 1090 of the first dummy channel structure 955. In some other implementations as shown in FIG. 10E, when the first dummy channel structure 955 does not include a high-K dielectric layer, portions of the functional layer 910 of the first dummy channel structure 955 can be removed during the formation of the GLSs 1060. the GLSs 1060 can expose the sidewall of the channel layer 920 of the first dummy channel structure 955.

In some implementations, the multiple GLSs 1060 can be formed by forming a mask layer (not shown) over the dielectric stack structure 720 and patterning the mask using, e.g., photolithography, to form slit openings covering the remaining sacrificial filling structures 860 in the remaining first through holes 771. A suitable etching process, e.g., dry etch and/or wet etch, can be performed to remove the remaining sacrificial filling structures 860 and portions of the dielectric stack structure 720 exposed by the slit openings until the multiple GLSs 1060 expose the substrate 710, as shown in FIGS. 10B and 10C. The mask layer can be removed after the formation of the multiple GLSs 1060. In some implementations, a doped region (not shown) can be formed at a bottom of each GLS 1060 in the substrate 710 by using any suitable doping process, such as ion implantation and/or thermal diffusion through the GLSs 1060. The dopant in the doped region can be any suitable N+ or P+ ions. After forming a conductive wall in the GLS 1060 in a subsequent process, the lower end of each conductive wall can be in contact with a corresponding doped region.

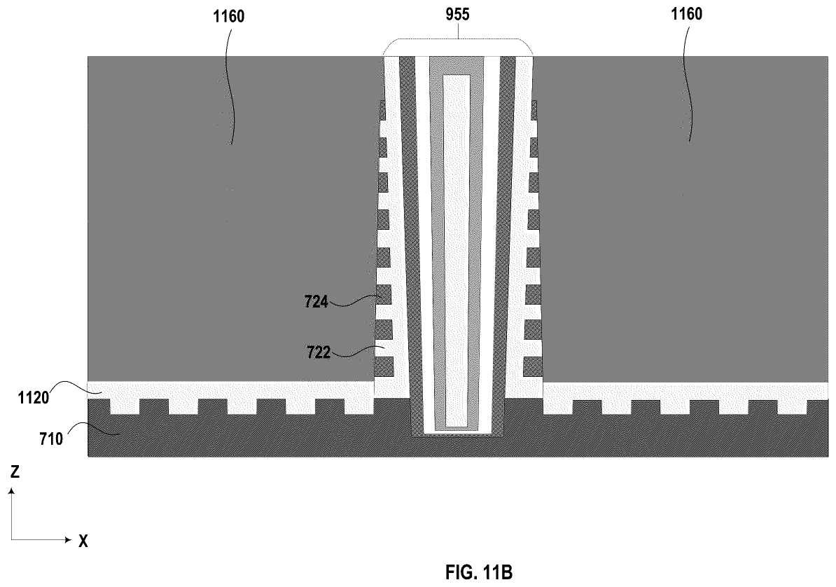

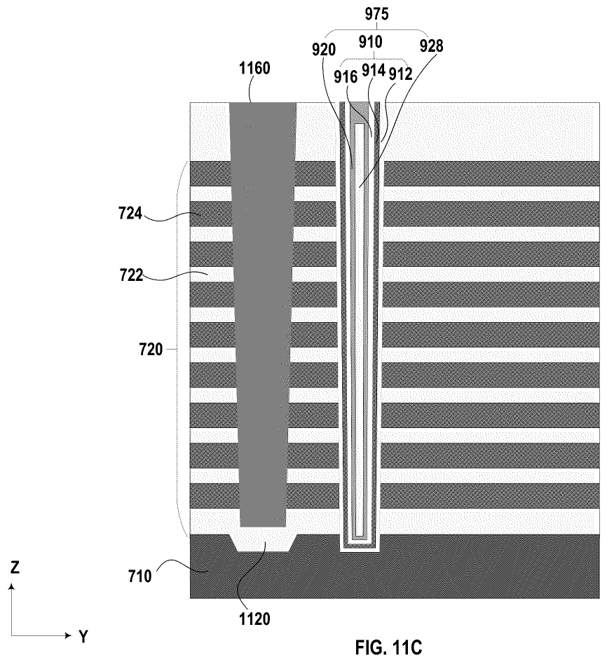

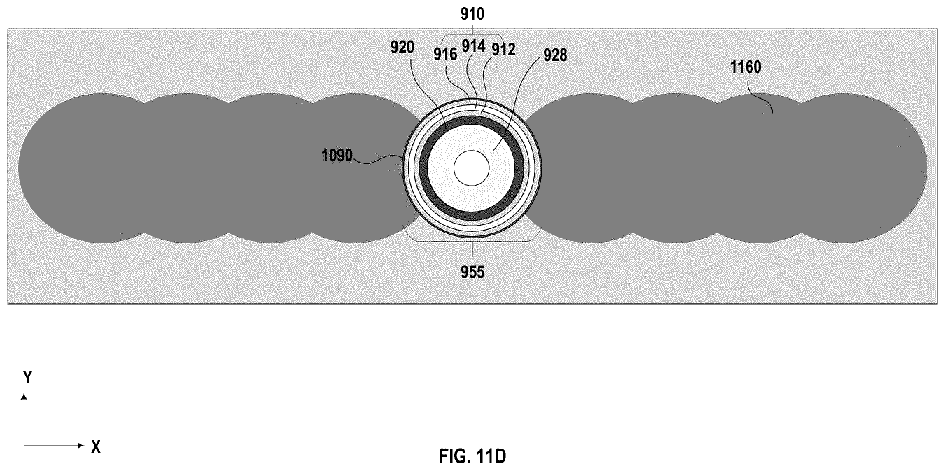

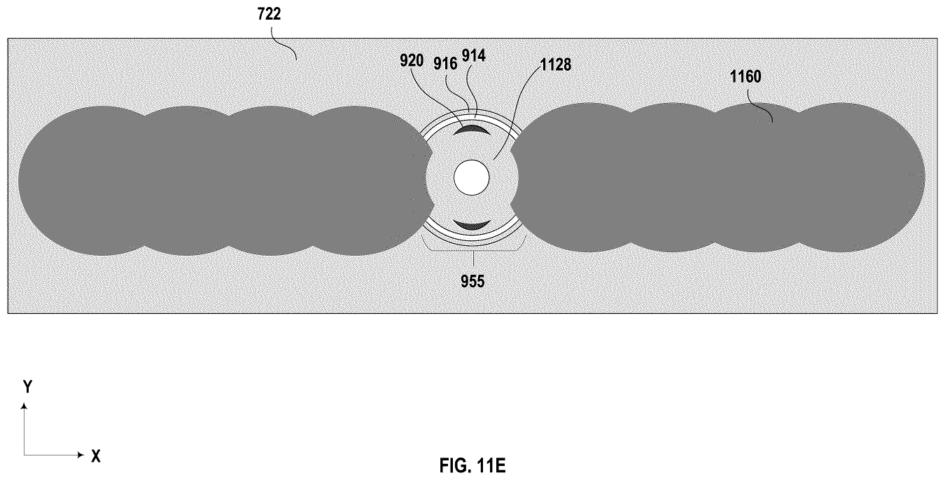

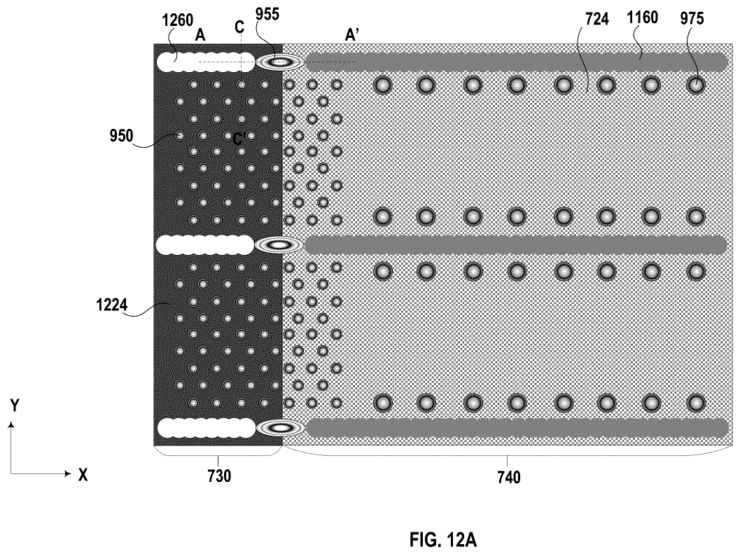

Referring back to FIG. 6, the method proceeds to operation 650, in which sacrificial slit structures can be formed in the GLSs. FIG. 11A illustrates a schematic diagram of the 3D structure after operation 650 in a top-down perspective view, according to some implementations of the present disclosure. FIG. 11B illustrates a schematic diagram of a portion of the 3D structure in a cross-sectional side view along the AA′ line shown in FIG. 11A, according to some implementations of the present disclosure. FIG. 11C illustrates a schematic diagram of a portion of the 3D structure in a cross-sectional side view along the BB′ line shown in FIG. 11A, according to some implementations of the present disclosure. FIG. 11D illustrates a schematic diagram of a portion of the 3D structure after operation 650 in an enlarged top-down view, according to some implementations of the present disclosure. FIG. 11E illustrates a schematic diagram of a portion of the 3D structure after operation 650 in an enlarged top-down view, according to some implementations of the present disclosure.

In some implementations, before forming the sacrificial slit structures 1160, in the GLSs 1060, a pre-oxidation process can be performed to form an oxide layer 1120 to protect the substrate 710, as shown in FIGS. 11B and 11C. It is noted that, when the GLSs 1060 expose the sidewall of the channel layer 920 of the first dummy channel structure 955 as shown in FIG. 10E, the pre-oxidation process can also oxidize portions of the channel layer 920 of the first dummy channel structure 955, as shown in FIG. 11E. As such, the oxidized portions of channel layer 920, the barrier layer 912, and the filling structure 928 of the first dummy channel structure 955 can form a first integrated filling structure 1128. The remaining portions of channel layer 920 of the first dummy channel structure 955 can be embedded in the first integrated filling structure 1128, as shown in FIG. 11E.

As shown in FIGS. 11A-11E, a plurality of sacrificial slit structures 1160 can then be formed in the GLSs 1060. A deposition process can be performed to fill the GLSs 1060 with any suitable sacrificial material (e.g., polysilicon) to form the sacrificial slit structures 1160. It is noted that, the sacrificial material of the sacrificial slit structures 1160 can have a sufficiently high etching selectivity in respect of the materials of the first dielectric layers 722 and the second dielectric layers 724, such that a subsequent etching process of the sacrificial slit structures 1160 can have minimal impact on the first dielectric layers 722 and the second dielectric layers 724. In some implementations, when the first dummy channel structure 955 includes a high-K dielectric layer 1090 as shown in FIG. 11D, the sacrificial slit structures 1160 can be in contact with the sidewall of the high-K dielectric layer 1090 of the first dummy channel structure 955. In some other implementations as shown in FIG. 11E, when the first dummy channel structure 955 does not include a high-K dielectric layer and portions of the functional layer 910 of the first dummy channel structure 955 are removed during the formation of the GLSs 1060 at operation 640, the sacrificial slit structures 1160 can be in contact with the sidewall of the channel layer 920 of the first dummy channel structure 955.

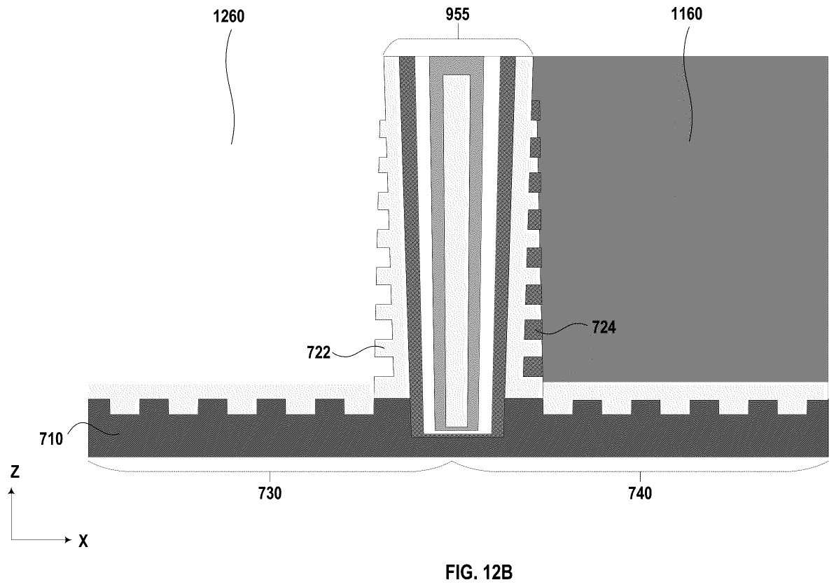

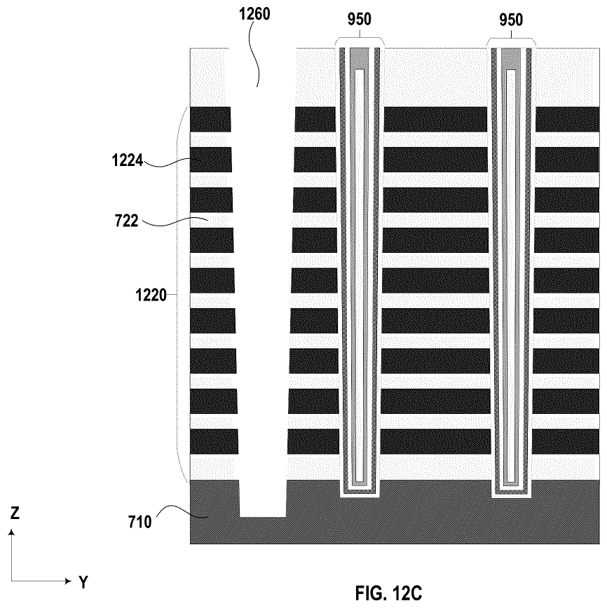

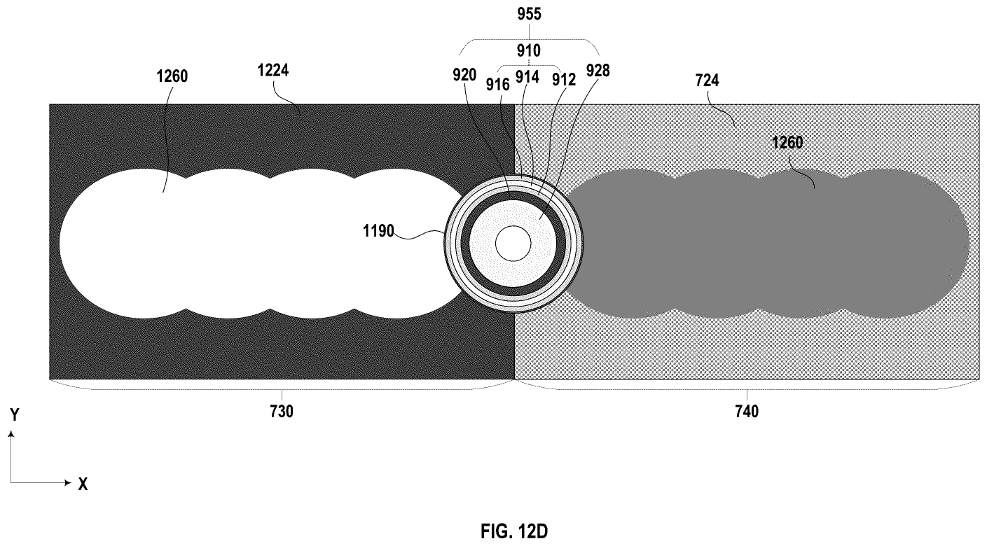

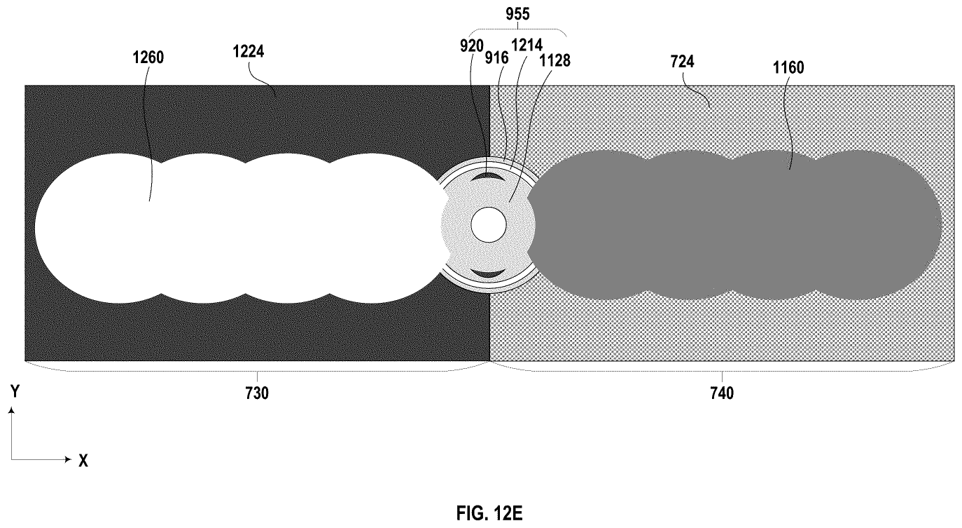

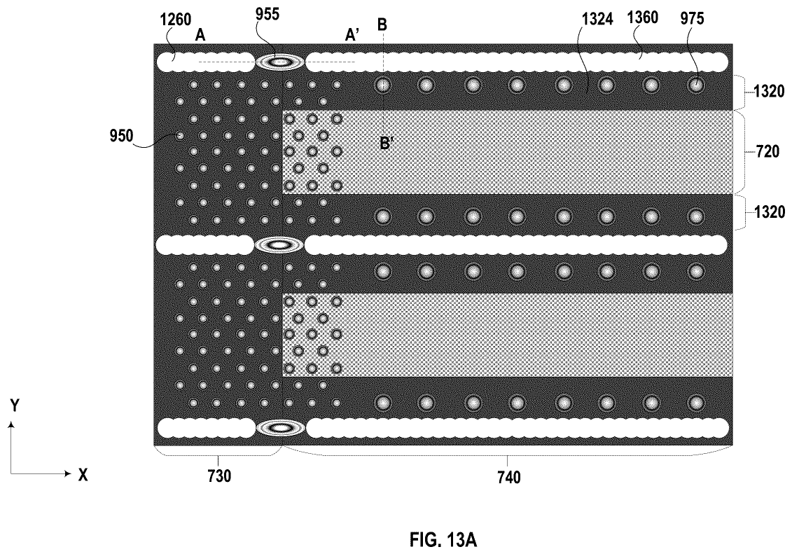

Referring back to FIG. 6, the method proceeds to operation 660, in which the sacrificial slit structures in the array region can be removed, and the second dielectric layers of the dielectric stack structure in the array region can be replaced by a plurality of conductive layers. FIG. 12A illustrates a schematic diagram of the 3D structure after operation 660 in a top-down perspective view, according to some implementations of the present disclosure. FIG. 12B illustrates a schematic diagram of a portion of the 3D structure in a cross-sectional side view along the AA′ line shown in FIG. 12A, according to some implementations of the present disclosure. FIG. 12C illustrates a schematic diagram of a portion of the 3D structure in a cross-sectional side view along the CC′ line shown in FIG. 12A, according to some implementations of the present disclosure. FIG. 12D illustrates a schematic diagram of a portion of the 3D structure after operation 660 in an enlarged top-down view, according to some implementations of the present disclosure. FIG. 12E illustrates a schematic diagram of a portion of the 3D structure after operation 660 in an enlarged top-down view, according to some other implementations of the present disclosure.

As shown in FIGS. 12A-12B and 12D-12E, the sacrificial slit structures 1160 in the array region 730 can be removed to form the GLSs 1260 in the array region 730 again. The sacrificial slit structures 1160 in the array region 730 can be removed by using any suitable etching process, e.g., an isotropic dry etch or a wet etch. The etching process can have sufficiently high etching selectivity of the sacrificial material of the sacrificial slit structures 1160 over the materials of the first dielectric layers 722, such that the etching process can have minimal impact on the first dielectric layers 722. As such, the GLSs 1260 in the array region 730 can be formed again.

In some implementations, the second dielectric layers 724 (e.g., silicon nitride) of the dielectric stack structure 720 in the array region 730 can be remove through the GLSs 1260. The second dielectric layers 724 in the dielectric stack structure 720 are used as sacrificial layers, and can be removed by using any suitable etching process, e.g., an isotropic dry etch or a wet etch. The etching process can have sufficiently high etching selectivity of the material of the second dielectric layers 724 over the materials of the first dielectric layer 722, such that the etching process can have minimal impact on the first dielectric layer 722. In some implementations, an etching time of the isotropic dry etch and/or the wet etch can be controlled, and a following cleaning process can be performed to completely remove the second dielectric layers 724 in the array region 730 in various directions to expose the top and bottom surfaces of each first dielectric layer 722. As such, multiple lateral trenches can be formed between first dielectric layers 722 in the array region 730. The multiple lateral trenches can extend in a lateral direction, and can be used as spaces for conductive layers to be formed in a subsequent process. It is noted that, due to the block by the first dummy channel structure 955 and the sacrificial slit structures 1160 in the contact region 740, the second dielectric layers 724 in the contact region 740 can be maintained.

In some implementations as shown in FIG. 12D, when the first dummy channel structure 955 includes a high-K dielectric layer 1190, the formed GLS 1260 in the array region 730 exposes the sidewall of the high-K dielectric layer 1190. In some other implementations as shown in FIG. 12E, when the first dummy channel structure 955 does not include a high-K dielectric layer, the storage layer 914 of the functional layer 910 of the first dummy channel structure 955 can be exposed by the GLS 1260. In such cases, the storage layer 914 (e.g., silicon nitride) can be also removed during removing the second dielectric layers 724 (e.g., silicon nitride) of the dielectric stack structure 720. As such, a curved slits 1214 can be formed, as shown in FIG. 12E.

As shown in FIG. 12C, a plurality of conductive layers 1224 can be formed in the lateral trenches. As such, the dielectric stack structure 720 can be transformed into a memory stack structure 1220 including multiple conductive/dielectric layer pairs. That is, a gate replacement process (also known as the “word line replacement” process) can be performed to replace second dielectric layers 724 (e.g., silicon nitride) of the dielectric stack structure 720 with conductive layers 1224. In some implementations, the multiple conductive layers 1224 can be used as word lines (i.e., gate electrodes) in the 3D memory device.

In some implementations, each conductive layers 1224 can be coated with one or more insulating layers (not shown) used as gate dielectric layers for insulating the respective word line (i.e., gate electrode). In some implementations, one or more insulating layers (not shown) can be formed in each of the multiple lateral trenches to cover the exposed surfaces of the lateral trenches with one or more suitable insulating materials. For example, one or more suitable deposition processes, such as CVD, PVD, and/or ALD, can be utilized to deposit the insulating materials into the lateral trenches. In some implementations, a recess etching and/or a CMP process can be used to remove excessive insulating material(s). The one or more insulating materials can include any suitable materials (e.g., high k-value dielectrics) that provide electric insulating function. For example, the one or more insulating materials can include silicon oxide, silicon nitride, silicon oxynitride, aluminum oxide, titanium nitride, etc., and/or any suitable combinations thereof. In some implementations, multiple insulating layers can have different insulating materials.

A conductive layer 1224 can be formed in each lateral trench between the one or more insulating layers. The conductive layer 1224 can be formed by filling the lateral trenches with a suitable gate electrode metal material. The conductive layer 1224 can provide the base material for the subsequently formed word lines (i.e., gate electrodes). The gate electrode metal material can include any suitable conductive material, e.g., tungsten, aluminum, copper, cobalt, or any combination thereof, for forming the word lines (i.e., gate electrodes). The gate electrode material can be deposited into lateral trenches using a suitable deposition method such as CVD, PVD, PECVD, sputtering, MOCVD, and/or ALD. In some implementations, the conductive layers 1224 can include tungsten formed by CVD. As such, the dielectric stack structure 720 in the array region 730 is transformed into a stack structure 1220 including alternating conductive/dielectric layers.

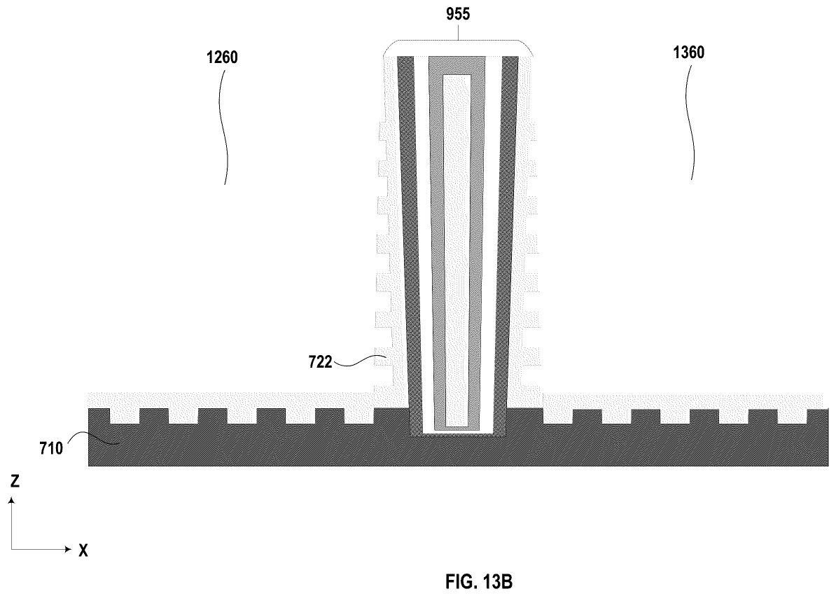

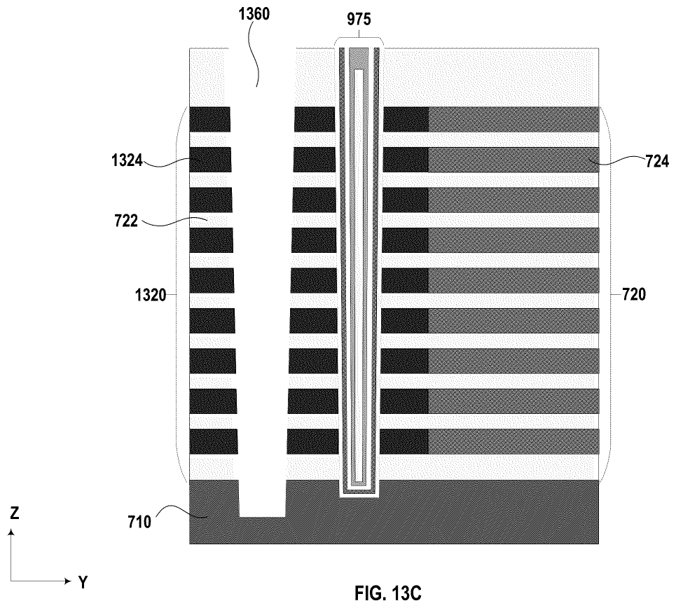

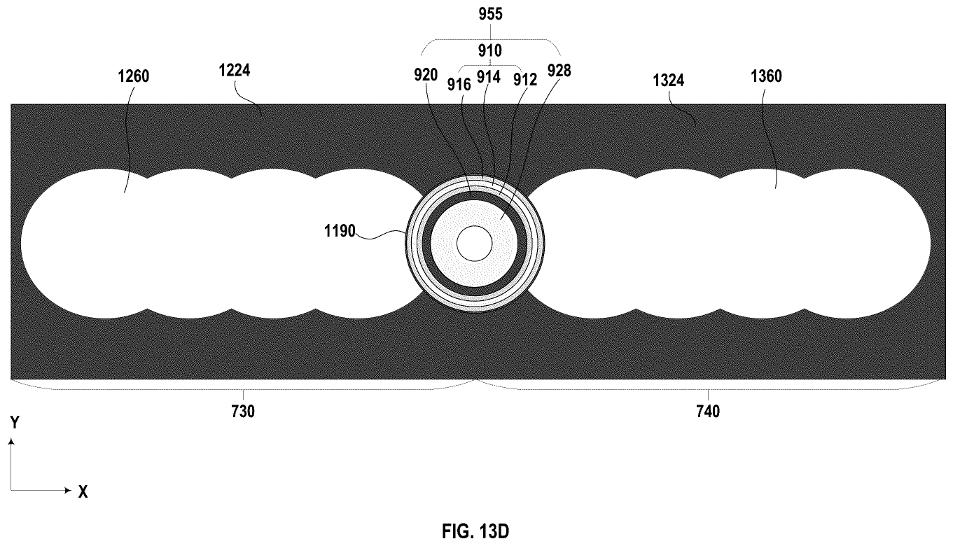

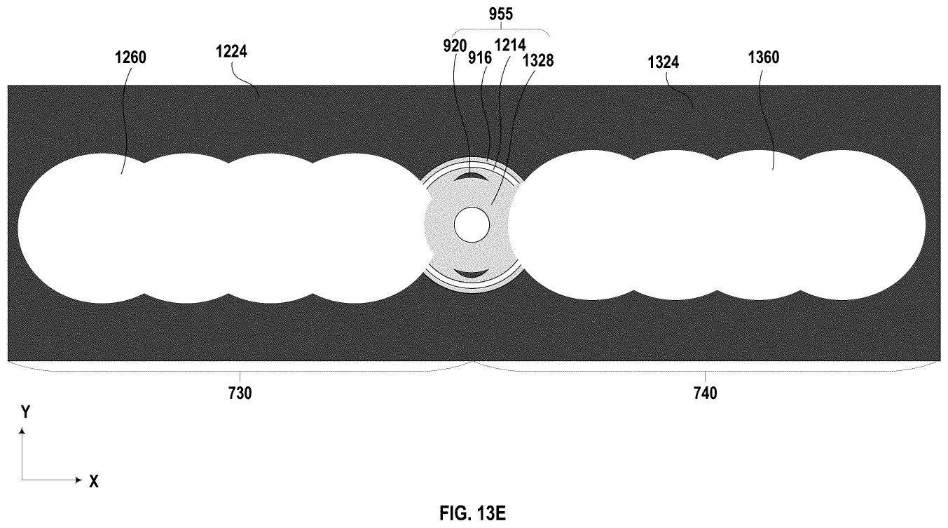

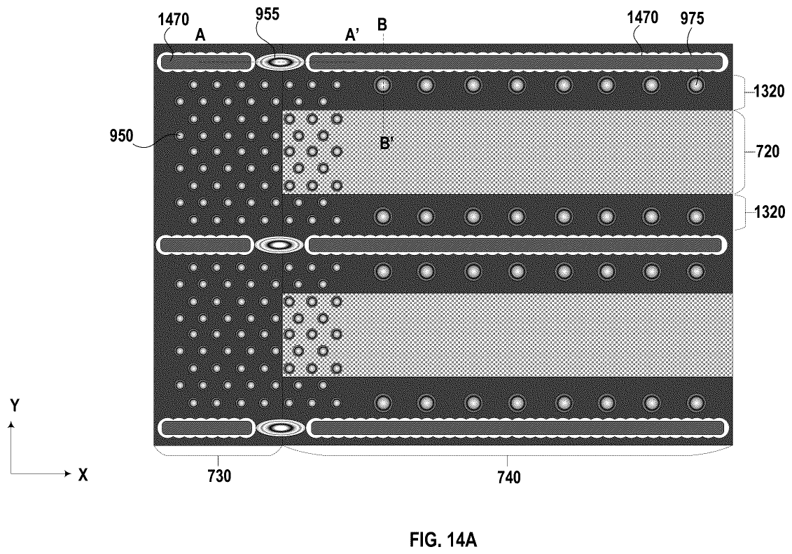

Referring back to FIG. 6, the method proceeds to operation 670, in which the sacrificial slit structures in the contact region can be removed, and portions of the second dielectric layers of the dielectric stack structure in the contact region can be replaced by a plurality of conductive layers. FIG. 13A illustrates a schematic diagram of the 3D structure after operation 670 in a top-down perspective view, according to some implementations of the present disclosure. FIG. 13B illustrates a schematic diagram of a portion of the 3D structure in a cross-sectional side view along the AA′ line shown in FIG. 13A, according to some implementations of the present disclosure. FIG. 13C illustrates a schematic diagram of a portion of the 3D structure in a cross-sectional side view along the BB′ line shown in FIG. 13A, according to some implementations of the present disclosure. FIG. 13D illustrates a schematic diagram of a portion of the 3D structure after operation 670 in an enlarged top-down view, according to some implementations of the present disclosure. FIG. 13E illustrates a schematic diagram of a portion of the 3D structure after operation 670 in an enlarged top-down view, according to some other implementations of the present disclosure.

As shown in FIGS. 13A-13B and 13D-13E, the sacrificial slit structures 1160 in the contact region 740 can be removed to form the GLSs 1360 in the contact region 740 again. Portions of the sacrificial slit structures 1160 in the contact region 740 adjacent to the GLSs 1360 can be removed by using any suitable etching process, e.g., an isotropic dry etch or a wet etch. The etching process can have sufficiently high etching selectivity of the sacrificial material of the sacrificial slit structures 1160 over the materials of the first dielectric layers 722, such that the etching process can have minimal impact on the first dielectric layers 722. As such, the GLSs 1360 in the contact region 740 can be formed again.

In some implementations, portions of the second dielectric layers 724 (e.g., silicon nitride) of the dielectric stack structure 720 in the contact region 740 that are adjacent to the GLSs 1360 can be remove through the GLSs 1360. The second dielectric layers 724 in the dielectric stack structure 720 are used as sacrificial layers, and can be removed by using any suitable etching process, e.g., an isotropic dry etch or a wet etch. The etching process can have sufficiently high etching selectivity of the material of the second dielectric layers 724 over the materials of the first dielectric layer 722, such that the etching process can have minimal impact on the first dielectric layer 722.

In some implementations, an etching time of the isotropic dry etch and/or the wet etch can be controlled, and a following cleaning process can be performed to partially remove the second dielectric layers 724 the contact region 740. As such, multiple lateral recesses can be formed between first dielectric layers 722 in the contact region 740. The multiple lateral recesses can extend in a lateral direction, and can be used as spaces for conductive layers to be formed in a subsequent process. It is noted that, due to the controlled etching time, portions of the second dielectric layers 724 in the contact region 740 having a distance from the GLSs 1360 can be maintained. As such, portions of the dielectric stack structure 720 adjacent to the GLSs 1360 can be transformed into conductive/dielectric stack structure 1320, and portions of the dielectric stack structure 720 having a distance from the GLSs 1360 can be maintained, as shown in FIG. 13C.

In some implementations, each conductive layers 1324 can be coated with one or more insulating layers (not shown) for insulating the respective conductive layers 1324. In some implementations, one or more insulating layers (not shown) can be formed in each of the multiple lateral trenches to cover the exposed surfaces of the lateral trenches with one or more suitable insulating materials. For example, one or more suitable deposition processes, such as CVD, PVD, and/or ALD, can be utilized to deposit the insulating materials into the lateral trenches. In some implementations, a recess etching and/or a CMP process can be used to remove excessive insulating material(s). The one or more insulating materials can include any suitable materials (e.g., high k-value dielectrics) that provide electric insulating function. For example, the one or more insulating materials can include silicon oxide, silicon nitride, silicon oxynitride, aluminum oxide, titanium nitride, etc., and/or any suitable combinations thereof. In some implementations, multiple insulating layers can have different insulating materials.

A conductive layer 1324 can be formed in each lateral recess between the one or more insulating layers. The conductive layer 1324 can be used as word line connection layers. The conductive layer 1324 can be formed by filling the lateral trenches with any suitable conductive material, e.g., tungsten, aluminum, copper, cobalt, or any combination thereof, for forming the word line connection layers. The conductive material can be deposited into lateral trenches using a suitable deposition method such as CVD, PVD, PECVD, sputtering, MOCVD, and/or ALD. In some implementations, the conductive layers 1324 can include tungsten formed by CVD.

In some implementations as shown in FIG. 13D, when the first dummy channel structure 955 includes a high-K dielectric layer 1190, the formed GLS 1360 in the contact region 740 exposes the sidewall of the high-K dielectric layer 1190. In some other implementations as shown in FIG. 13E, when the first dummy channel structure 955 does not include a high-K dielectric layer, and the curved slits 1214 expose a sidewall of the sacrificial slit structures 1160 in the contact region 740, an oxidation process during the formation of the conductive layers 1324 can also oxidize the exposed sidewall of the sacrificial slit structures 1160. As such, the formed second integrated filling structure 1328 has a concave sidewall exposed by the GLS 1360 in the contact region 740, and a convex sidewall exposed by the GLS 1260 in the array region 730, as shown in FIG. 13E.

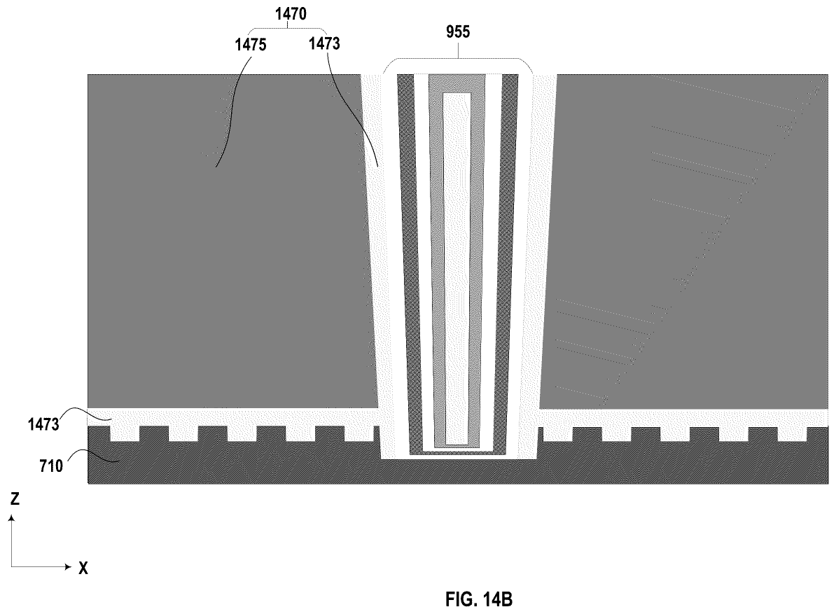

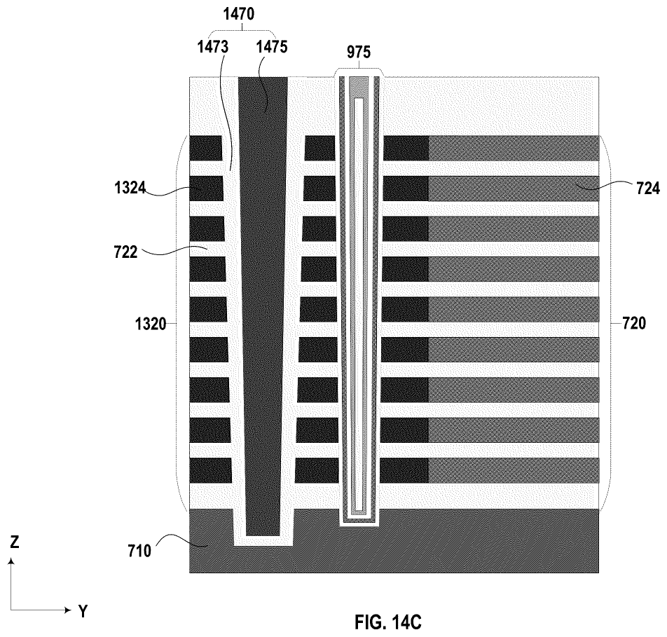

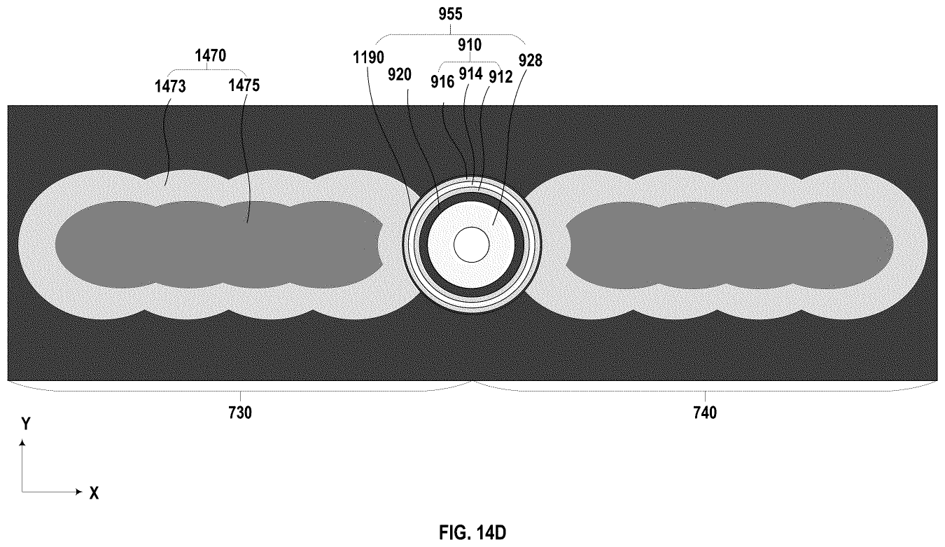

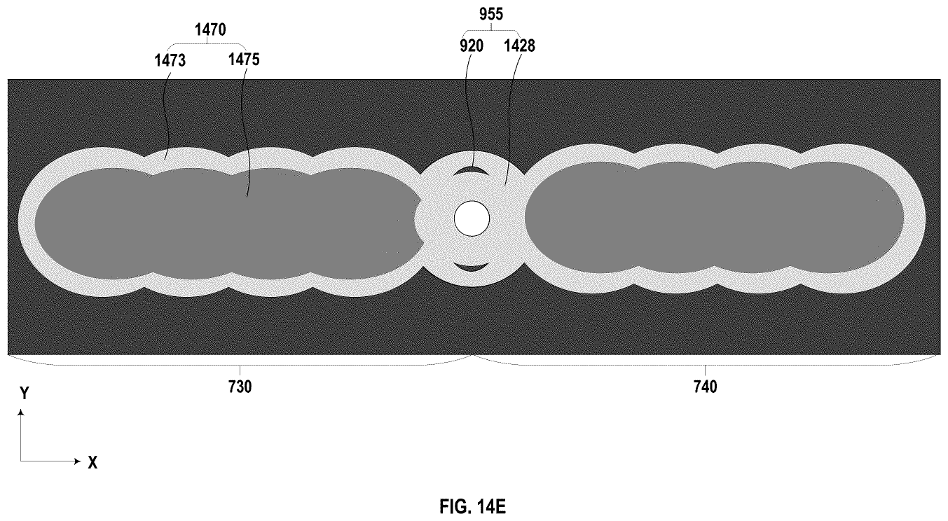

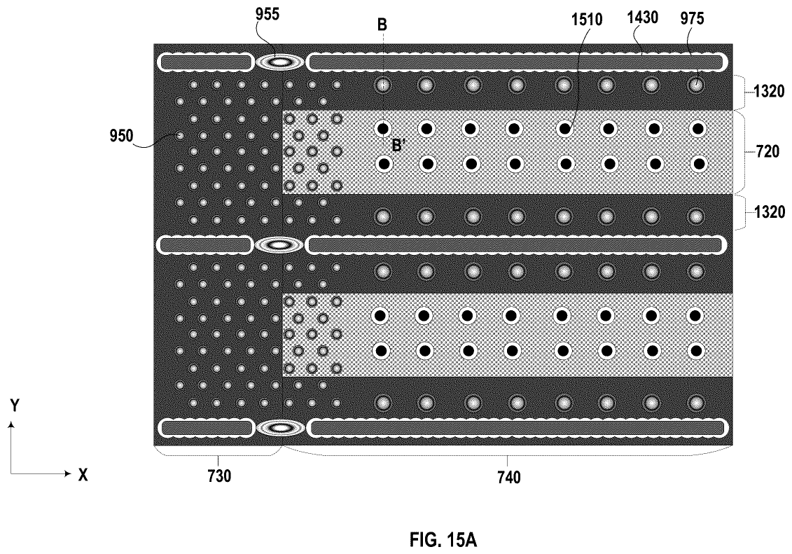

Referring back to FIG. 6, the method proceeds to operation 680, in which a plurality of GLS structure segments can be formed in the GLSs. FIG. 14A illustrates a schematic diagram of the 3D structure after operation 680 in a top-down perspective view, according to some implementations of the present disclosure. FIG. 14B illustrates a schematic diagram of a portion of the 3D structure in a cross-sectional side view along the AA′ line shown in FIG. 14A, according to some implementations of the present disclosure. FIG. 14C illustrates a schematic diagram of a portion of the 3D structure in a cross-sectional side view along the BB′ line shown in FIG. 14A, according to some implementations of the present disclosure. FIG. 14D illustrates a schematic diagram of a portion of the 3D structure after operation 680 in an enlarged top-down view, according to some implementations of the present disclosure. FIG. 14E illustrates a schematic diagram of a portion of the 3D structure after operation 680 in an enlarged top-down view, according to some other implementations of the present disclosure.

As shown in FIGS. 14A-14E, a plurality of GLS structure segments 1470 can be formed in the GLSs 1260/1360. In some implementations, the fabricating process for forming the GLS structure segments 1470 can include forming a second insulating layer 1473 on the sidewalls of the multiple GLSs 1260/1360. The second insulating layer 1473 is also referred as a gate line spacer (GLSP) layer, and can be used to provide electrical insulation between the multiple conductive layers 1224/1324 and a conductive wall formed in a subsequent process.

In some implementations, the fabricating process for forming second insulating layer 1473 can include a conductive layer recess process. Portions of the multiple conductive layers 1224/1324 exposed by the GLSs 1260/1360 can be removed by a recess etching process. In some implementations, in order to ensure the insulation between multiple conductive layers 1224/1324, a recess etching process, such as a wet etching process, can be performed to remove portions of the multiple conductive layers 1224/1324 exposed by the GLSs 1260/1360. In doing so, a recess can be formed in each lateral trench adjacent to the GLSs 1260/1360.

In some implementations, the second insulating layer 1473 can have a laminated structure (not shown) including two or more spacer sublayers formed by using any suitable deposition processes, such as atomic layer deposition (ALD) processes. For example, the second insulating layer 1473 can include a first spacer sublayer (not shown) covering the sidewall of the GLSs 1260/1360 and the exposed surfaces of the multiple conductive layers 1224/1324. The first spacer sublayer can include a low temperature oxide material, such as silicon oxide, configured to prevent the multiple conductive layers 1224/1324 from being oxidized in the subsequent processes. The second insulating layer 1473 can further include a second spacer sublayer (not shown) to cover the first spacer sublayer. The second spacer sublayer can include a high k-value material, such as silicon nitride. Such laminated structure can efficiently increase the equivalent oxide thickness (EOT) of the second insulating layer 1473, thereby improving the isolation performance of the second insulating layer 1473.

In some implementations, the fabricating process for forming the GLS structure segments 1470 can include forming a conductive wall 1475 in each GLSs 1260/1360. The conductive wall 1475 can be in contact with the doped region (not shown) in the substrate 710, and is used as an array common source (ACS) of the multiple NAND strings. In some implementations, the conductive wall 1475 can be formed by depositing a conductive material, such as polysilicon, silicides, tungsten, aluminum, copper, and/or combinations thereof, etc. The conductive material can be deposited into the multiple GLSs 1260/1360 using a suitable deposition method such as CVD, PVD, PECVD, sputtering, MOCVD, and/or ALD. A following CMP process can be performed to planarize the top surface of the formed 3D structure.

It is noted that, in some implementations as shown in FIG. 14E, when the first dummy channel structures 955 does not include a high-K dielectric layer, the curved slits 1214 can be filled with the dielectric material during forming the second insulating layer 1473. As such, the tunneling layer 916, the second integrated filling structure 1128, as well as the filled the dielectric material in the curved slits 1214 can form a third integrated filling structure 1328, while the remaining portions of the channel layer 920 are embedded within the third integrated filling structure 1328, as shown in FIG. 14E. In some other implementations as shown in FIG. 14D, when the first dummy channel structures 955 includes the high-K dielectric layer 1090, the first dummy channel structure 955 can keep the complete structure and separated from the GLS structure segments 1470 by the high-K dielectric layer 1190.

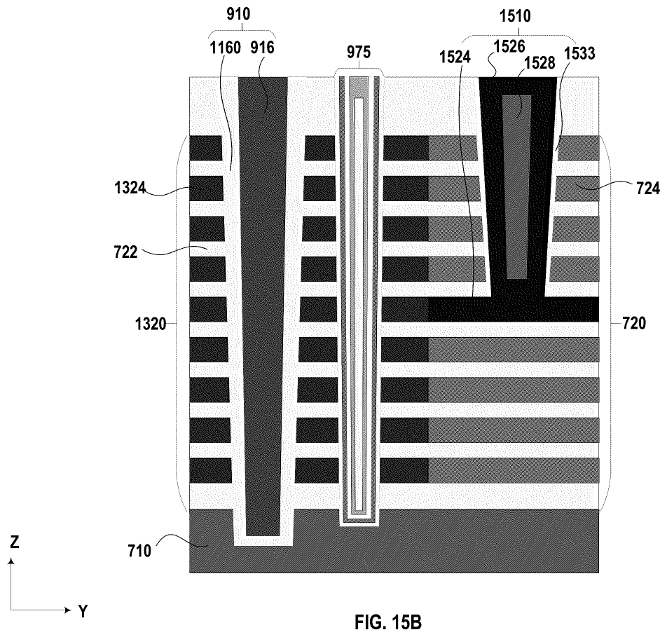

Referring back to FIG. 6, the method proceeds to operation 690, in which a plurality of contact structures can be formed in the dielectric stack structure in the contact region. FIG. 15A illustrates a schematic diagram of the 3D structure after removing a subset of dummy contacts at operation 690 in a top-down perspective view, according to some implementations of the present disclosure. FIG. 15B illustrates a schematic diagram of a portion of the 3D structure in a cross-sectional side view along the BB′ line shown in FIG. 15A, according to some implementations of the present disclosure.

As shown in FIGS. 15A and 15B, a plurality of contact structures 1510 can be formed in the plurality of contact holes in the dielectric stack 720 in the contact region 740. In some implementations, forming the contact structures 1510 can include forming a plurality of contact holes in the dielectric stack structure 720 in the contact region 740. In some implementations, the plurality of contact holes can each penetrate through an upper portion of the dielectric stack 720 in the contact region 740 and stopping at one corresponding second dielectric layer 724. For example, one or more suitable etching processes, e.g., dry etch and/or wet etch, can be performed to remove portions of the dielectric stack 720 in the contact region 740 to form plurality of contact holes. A mask layer (not show) can be used to control the shape of the contact holes during the etching process, and various etching time can be controlled to form the plurality of contact holes with different depths.

In some implementations, dielectric filling structure can be formed to fill each contact hole by any suitable deposition process. A punch etching can be performed to remove a portion of the dielectric filling structure to expose a corresponding one second dielectric layer 724 at the bottom of each contact hole. The remaining portion of the dielectric filling structure forms a spacer layer 1533 on the sidewall of each contact hole. A portion of the exposed second dielectric layer 724 can be removed by any suitable etching process to lateral expose one corresponding conductive line 1324 at a same level of the corresponding one second dielectric layer 724.

A conductive layer (including 1524 and 1526) can be formed by any suitable thin film deposition process using a first conducive material to cover the spacer layer 1572 and the bottom surface of each contact hole, and in contact with the one corresponding conductive line 1324 in a lateral direction. In some implementations, a second conductive material can then be filled in the contact holes to form a conductive filling structure 1528. The first and second conductive materials can be deposited into the contact holes using any suitable deposition method such as CVD, PVD, PECVD, sputtering, MOCVD, and/or ALD. In some implementations, the conductive layer (including 1524 and 1526), and the conductive filling structure 1528 can include any suitable conductive material, e.g., tungsten, aluminum, copper, cobalt, or any combination thereof.

The conductive layer 1526 and the conductive filling structure 1528 can form a conductive via isolated from other conductive lines 1320 by the spacer layer 1533. That is, the contact structure 1510 can include a conductive via (including 1526 and 1528) and a landing conductive layer 1524. The landing conductive layers 1524 can each be laterally in contact with a corresponding conductive layer 1324 in the conductive/dielectric stack structure 1320 in the contact region 740. The conductive via 1540 is in direct contact with the landing conductive layer 1524, and is electrically connected to the corresponding conductive layer 1324. As such, the formed contact structures 1510 can be used as word line contacts.

Accordingly, 3D memory devices and fabricating methods are provided. Based on the GLS expansion process, the patterning process of the channel holes, GLS openings, and through holes can be merged into a single mask. The memory finger supports can be designed between GLS structures segments by cancelling the traditional long GLS isolation structure. Dummy channel structures can be used as memory finger supports and can be formed in the same processes of forming the channel structures. And the isolation function can be realized through a silicon nitride recess process and oxide deposition process, and together with the short GLS structures segments.

Since there is no long GLS that runs through the entire plane, the risk of unstable structure due to stress can be suppressed by using short GLS structures segments and memory finger supports. The filled oxide and polysilicon material in the short GLS structures segments and memory finger supports can significantly decrease device defects including memory finger crooking/collapse and/or wafer bow effects. Further, by merging the contact formation processes and the GLS structure formation processes, the application of photolithography process can be reduced, thereby reducing the process difficulty and the production costs. In summary, the present disclosure can solve the fabricating issues caused by structural stresses, thereby breaking the technical bottleneck in the research and development of higher-level 3D memory devices.

The foregoing description of the specific implementations will so fully reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A semiconductor device, comprising:
a stack structure comprising an array region and a contact region; and
a gate line slit structure extending vertically through the stack structure and laterally along a first lateral direction to divide the stack structure into memory blocks, the gate line slit structure comprising:
a first dummy channel structure located at a boundary between the array region and the contact region,
a first gate line slit segment extending laterally from the first dummy channel structure into the array region, and
a second gate line slit segment extending laterally from the first dummy channel structure into the contact region.

2. The semiconductor device of claim 1, further comprising:
channel structures each vertically extending through the stack structure and located in the array region; and
second dummy channel structures each vertically extending through the stack structure and located in the contact region.

3. The semiconductor device of claim 2, wherein:
the stack structure in the array region comprises conductive layers and first dielectric layers alternatively stacked in a vertical direction; and
the stack structure in the contact region comprises:
a first contact portion adjacent to the second gate line slit segment and comprising the conductive layers and the first dielectric layers alternatively stacked in the vertical direction, and
a second contact portion separated from the second gate line slit segment by the first contact portion, and comprising first dielectric layers and second dielectric layers alternatively stacked in the vertical direction.

4. The semiconductor device of claim 3, wherein:
the second dummy channel structures are each vertically extending through the first contact portion.

5. The semiconductor device of claim 1, wherein:
a first width of the first dummy channel structure along the first lateral direction is greater than a second width of the first dummy channel structure along a second lateral direction perpendicular to the first lateral direction.

6. The semiconductor device of claim 1, wherein:
the first dummy channel structure comprises a high-k layer, a first oxide layer, a nitride layer, a second oxide layer, a semiconductor layer, and a filling structure.

7. The semiconductor device of claim 1, wherein:
the first dummy channel structure comprises an oxide structure and semiconductor segments laterally surrounded by the oxide structure.

8. The semiconductor device of claim 7, wherein the oxide structure comprises:
a convex sidewall surface adjacent to the first gate line slit segment; and
a concave sidewall surface adjacent to the second gate line slit segment.

9. The semiconductor device of claim 3, wherein:
each of the first gate line slit segment and the second gate line slit segment comprises a wall structure laterally extending in the first lateral direction and insulated from the conductive layers.

10. The semiconductor device of claim 3, further comprising:
gate line contact structures each comprising:
a conductive landing layer in the second contact portion and laterally in contact with a corresponding conductive layer; and
a conductive via vertically through the second dielectric layers and first dielectric layers above the conductive landing layer and in contact with the conductive landing layer.

11. A method for forming a semiconductor device, comprising:
forming a dielectric stack comprising alternative second dielectric layers and first dielectric layers;
forming a row of first through holes laterally aligned along a first lateral direction, and each vertically through the dielectric stack,
forming sacrificial filling structures in the first through holes;
removing the sacrificial filling structure from one first through hole at a boundary between an array region and a contact region;
forming a first dummy channel structure in the one first through hole;
removing the sacrificial filling structures from the other first through holes and portions of the dielectric stack to form a first trench in the array region and a second trench in the contact region; and
forming a first gate line slit segment in the first trench and a second gate line slit segment in the second trench.

12. The method of claim 11, when forming the row of first through holes, further comprising:
forming second through holes in an array region; and
forming third through holes in a contact region and adjacent to the first through holes;
wherein a first distance between adjacent first through holes is less than a second distance between adjacent second through holes.

13. The method of claim 12, further comprising:
forming sacrificial filling structures in the second through holes and the third through holes;
removing the sacrificial filling structures from the second through holes and the third through holes;
forming channel structures in the second through holes; and
forming second dummy channel structures in the third through holes.

14. The method of claim 13, further comprising:
forming a first sacrificial wall in the first trench and a second sacrificial wall in the second trench;
removing the first sacrificial wall to reopen the first trench;
replacing the second dielectric layers in the array region to conductive layers through the reopened first trench;
removing the second sacrificial wall to reopen the second trench; and
replacing portions of the second dielectric layers in the contact region that are adjacent to the second trench to conductive layers.

15. The method of claim 14, wherein forming the first dummy channel structure comprises:
forming a first oxide layer on a sidewall of the one first through hole;
forming a nitride layer on the first oxide layer;
forming a second oxide layer on the nitride layer;
forming a semiconductor layer on the second oxide layer; and
forming a filing structure on the semiconductor layer to fill the one first through hole.

16. The method of claim 15, further comprising:
when removing the sacrificial filling structures from the other first through holes and portions of the dielectric stack, further removing portions of the first oxide layer, the nitride layer, and the second oxide layer, to expose sidewalls of the semiconductor layer in the first and second trenches;
oxidizing exposed sidewalls of the semiconductor layer;
when replacing the second dielectric layers in the array region, further removing remaining portions of the nitride layer to form curved openings; and
oxidizing portions of the second sacrificial wall exposed by the curved openings.

17. The method of claim 16, further comprising:
forming a high-k layer on the sidewall of the one first through hole;
wherein the first oxide layer is formed on the high-k layer.

18. The method of claim 11, wherein forming the first and second gate line slit segments comprises:
forming an insulating layer on sidewalls and bottoms of the first and second trenches; and
forming wall structures on the insulating layer to fill the first and second trenches.

19. The method of claim 16, further comprising:
forming a gate line contact structure through a remaining portions of the dielectric stack in the contact region, and in contact with a corresponding conductive layer in the contact region, comprising:
forming a contact hole though portions of the dielectric stack to expose one sacrifice layer in a same level of the corresponding conductive layer;
removing portions of the one sacrifice layer to form a lateral recess to expose the corresponding conductive layer;
forming a landing conductive layer in the lateral recess and in contact with the corresponding conductive layer; and
forming a conductive via in the contact hole to contact with the landing conductive layer.

20. A memory device, comprising:
a stack structure comprising:
a first conductive/dielectric stack in an array region,
a second conductive/dielectric stack in a contact region, and
a dielectric stack in the contact region;
a gate line slit structure extending vertically through the stack structure and laterally along a first lateral direction to divide the stack structure into memory blocks, the gate line slit structure comprising:
a first dummy channel structure located at a boundary between the array region and the contact region,
a first gate line slit segment extending laterally from the first dummy channel structure into the array region, and
a second gate line slit segment extending laterally from the first dummy channel structure into the contact region;
channel structures each extending vertically through the first conductive/dielectric stack;
second dummy channel structures each extending vertically through the second conductive/dielectric stack and adjacent to the second gate line slit segment; and
gate line contact structures each extending vertically in the dielectric stack and laterally in contact with corresponding conductive layers of the second conductive/dielectric stack.
